(19) United States
(12) Patent Application Publication
(10) Pub. No.: US 2006/0259199 A1
(43) Pub. Date: Nov. 16, 2006

(54) Method and a system for automatic management of demand for non-durables

(76) Inventors: Jan Ove Gjerde, Oslo (NO); Khoi Tien Vu, San Jose, CA (US)

Correspondence Address: PATTERSON & SHERIDAN, L.L.P., 3040 POST OAK BOULEVARD, SUITE 1500, HOUSTON, TX, 77056, US

(21) Appl. No.: 10/559,368

(22) PCT Filed: Jun. 7, 2004
(86) PCT No.: PCT/NO04/00163

§ 371 Date: Apr. 21, 2006

(30) Foreign Application Priority Data
Jun. 5, 2003 (NO) 2003 2546
Jun. 5, 2003 (NO) 2003 2547

(51) Int. Cl. H03J 3/14

(52) U.S. Cl. 700/284; 455/420; 700/295

(57) ABSTRACT

Automatic management of demand for non-durables like electrical energy, gas, thermal energy and fresh water is provided by a two-way communication network between a Multi Utility provider (20) and many respective End-users (5). Specialized electronic boxes (27, 28) at the End-users' premises receive broadcast dowlink signals from the Multi Utility provider (20), initiate metering action and transmit to the Multi Utility Provider uplink return signals containing instant or semi-instant non-durables consumption values, thereby collectively influencing the Multi Utility provider's pricing of non-durables.

The present invention relates to a method and a system for automatic management of demand for non-durables like electric power, gas, thermal energy, fresh water and the like. In further aspects, the invention also relates to a computer program product, a control broadcast signal and a data return communication signal, all for use in the method and system of the invention.

### BACKGROUND OF THE INVENTION

The consumption of electrical energy is increasing worldwide, but investment in new power transmission and power distribution networks and/or energy generation capacity has become increasingly difficult.

This is due to factors including increased load on the environment in the form of CO₂ emissions and to an unwillingness to invest in deregulated and/or fast-changing energy markets.

Due to these facts, there has in recent years been a great deal of interest in achieving a more optimal utilization of the installed assets by the power industry, regulatory bodies, environmental bodies and the governmental bodies, with respect to power generation, transmission and distribution power networks. Also a more optimal utilization of the total energy use and consumption to all types of End-users are put on the agenda by the players themselves, environmental bodies and the governmental bodies.

Generation, transmission and distribution capacity is dimensioned according to the installed peak electrical load, with extra capacity (or security margin) in generation and transmission to handle likely unplanned outages, due to a fault in the power network, wrong actions performed by the power system operators, malfunctioning of components or other unforeseen disturbances in the power network, etc. A standard practice for almost every power system operator worldwide is that the power system shall revert to a secure, stable and reliable power supply if one primary component is going out of service due to disturbances or due to a scheduled outage. This security margin is denoted as the N-1 criterion.

Most of the electrical power systems have a huge variation of the electrical load connected over a 24 hour period. The power grid primary components, such as power cables, overhead lines, transformers and switch gears, must all be designed to withstand the peak electrical load of the electrical power system. These peak electrical loads normally only occurs for a few percent of the time over a 24 hour period. For average electrical utility, off-peak electrical load is around a third of the electrical peak load.

A well known approach to meet the electrical load demand is peak shaving of the electrical load curve, i.e. Demand Side Management (DSM). This approach is intended to increase the utilization and the efficiency of the electrical power system, and thereby postpone investments in the transmission or the distribution system, and/or in installed generation capacity.

One of the approaches to perform DSM is use of two-way communication systems (2WC system). Technology and complete solutions for 2WC systems have been available in the market place for several years, both in US and globally. 2WC systems are a communication infrastructure system which establishes direct communication paths between the Electrical Utility or a Multi Utility and the End-users and vice versa.

U.S. Pat. No. 4,264,960 describes a method and apparatus which permits a power electrical utility to have direct control over customer's loads for facilitating load management philosophy including load shaving and load deferral. The system includes a master station and a plurality of remote receiver units positioned at, and connected to control the on and off times of customers loads. The remote receiver units are controlled by signals from substations consisting of pulse code signals injected into the power network lines.

U.S. Pat. No. 4,360,881 relates to energy consumption control and method for use by a utility company for reducing energy consumption during peak hours. The system includes a centralized code signal generator selectively generating one or more distinguishable control codes, a multiplexer for impressing these control codes upon the carrier of of an existing commercial broadcast station, and a plurality of radio receivers each stationed at a selected customer location for disconnecting selected appliances upon receipt of one of said control codes. Each receiver includes a signal detector for detecting the reception of one of said signal codes and a disconnect switch for disconnecting selected appliances of the customers upon detection of one said control codes. A timer may be used for sustaining the operation of the disconnect switch after detection of one of said control for a predetermined period of time. Alternatively, a latching relay on microprocessor scheme may be used in which cases the appliances will remain disconnected until the transmission of a second control code is detected.

U.S. Pat. No. 4,686,630 describes a load management control system and method which communicates load shedding information from a central station controller via existing telephone lines to a substation controller. The substation controller sends encoded step voltage signals down a power line to a load control receiver.

Systems and methods for power and energy management including load shaving often have a drawback in that one ore more sets of specially designed devices are required to be connected to the high voltage parts of a power network in order to encode or decode communication signals. Existing systems for automatic electrical load management also often requires one or more separate communication infrastructures, and many of them are time-based. However, if for example a peak load occurred at an unexpected time of day, the time-based system may have failed to reduce or smooth the electrical load.

A well known drawback with existing power management systems based on shedding of electrical loads is that upon restoration of a power system, the magnitude of the electrical load to be reconnected is, in practice unknown. In consequence, restoration after load shedding tends to take long time. Electrical loads that have been shed have to be re-energized in a predetermined way, one-by-one under careful monitoring, to avoid creating new disturbances in the power system that would lead to new problems and possibly to further load disconnections.

Some recent systems have improvements based on Internet communication and/or standards associated with Internet. U.S. Pat. No. 5,862,391 describes an extensive power management system comprising computers equipped for bus communication over a Modbus field bus connected to one ore more DDE servers (Dynamic Data Exchange). The computers contain various software packages involved in monitoring and controlling selected aspects of power usage/consumption. Communications are described using TCP/IP (Transmission Control Protocol/Internet Protocol) via Ethernet LANs (Local Area Networks). Field devices such as General Electric EPM3720 consumption meter unit are described as being continuously polled by the DDE server carry out power management functions using Modbus RTU protocol.

EP814 393 A1 describes use of the Internet as a part of a method to communicate with electrical components, principally appliances in the home, for the purpose of supervision and control. The method requires an intelligent socket to be added to each appliance together with the use of a signal superimposed on a power distribution network to communicate control signals.

US2002/0010690 A1 describes an energy information system and sub-measurement board for use therewith. Generally, the disclosure relates to a communication enabled-energy information system and sub-measurements board for use therewith. Particularly, the disclosure relates to an energy information system having a sub-measurement board which measures power consumptions of individual circuits of a customer's distribution load panel and which is capable of providing cumulative periodic consumption data of the customer's other metered utilities. Specifically, the disclosure relates to an energy information system which transmits load profile data of individual electric circuits back to the energy information service provider for processing into a format which is accessible by the energy information service provider for internal use and accessible for the customer for monitoring energy usages of specific circuits loads, such as heating, air-conditioning, lighting, etc. and which can provide the cumulative periodic consumption data for all the customer's metered utilities such as electric, gas and water.

WO 01/73636 A1 describes a method and a system for metering consumer non-durables, in particular electricity, gas and water. The disclosure relates to a method and a system for metering, i.e. measuring and measurement parameter reporting, of consumer non-durables, in particular electric, gas and water, using telecommunication between a meter position and a central data base.

US2001/0010032 A1 describes an energy management and building automation system. The invention relates to the field of home or business automation and to electrical power distribution management. More particularly the invention relates to a computer-controlled system for demand side management of electrical loads in residential and commercial premises and for otherwise controlling these loads. The system preferably uses power line carrier (PLC) technology within the premises for communication between a control computer and the loads, and PLC or RF technology for communications with the facility's (i.e. customers) local watt-hour meter supplied by the utility company.

NO314557 describes a method for control and communication. The invention is connected to monitoring and control of power generation, a transmission network and a distribution network. Specifically, the invention is a method, a system and a computer program for control of medium voltage devices connected to a medium voltage power distribution network.

US006102487A discloses a system in which a central facility controls electrical-heating devices at many End-user locations. Each End-user sets a preferred temperature profile for the day. This information is uploaded to the central facility via a data network such as the Internet. By correlating all the End-users' profiles with the capability of the power grid, the central facility determines an actual power profile for each End-user. The actual power profiles are then sent down to the sites to turn on or turn off the heating devices. For this downlink, it is proposed that the mobile radio communication be used, and that each site be assigned two phone numbers—an individual number (unique to each site), and a group number (shared among several sites).

While combining the use of several communications networks and taking into consideration the capability of the power grid, the invention in US006102487A suffers from a number of drawbacks:
it takes a person with considerable skills (i.e., a trained technician) to install the necessary equipment at each site, meaning that a wide-scale deployment (or mass market) would be slow and costly,
the invention focuses exclusively on electrical-heating,
an extension to a large number of End-users and to other types of load is difficult because the phone network has limited capacity,
there is a concern for privacy because the End-user's profiles (which imply their habits of energy usage, whether they are at home or not, etc.) are reported to the central facility.

Generally, reading of the metering devices connected to the non-durables at every End-user's location is of vital interest for the business of power generation companies, a Multi Utility (Electrical Utilities, Thermal Energy utilities, Fresh water utility, Gas utility, etc.), the Wholesalers, Service Providers (SP), Energy Service Providers (ESP) or other players delivering one or more of the non-durables to End-users.

With respect to electrical energy delivery, reading of the electrical metering devices at the End-user's location is of vital interest for the business of an Electrical Utility and the Wholesalers. Earlier it was the Electrical Utility itself that performed the electrical meter reading manually by visiting the different End-user's installations.

Although these systems, devices and methods mentioned above are adequate for the purposes which they are intended, these inventions do not disclose any two-way energy information system taking into account all players in the energy business by use of a communication infrastructure by means of commercial radio.

The present invention does not exclude any existing AMR scheme. In fact, if AMR is already deployed in a geographical area, this invention simply uses that AMR as the upstream path for communicating the consumption of non-durables (hourly consumption) to the local Multi Utility and/or to the Service Provider's back office. However, a typical AMR deployment is slow, costly and in many instances, not technically reliable. For these reasons, this invention describes a low-cost means for building the upstream communication path of the 2WC system.

Therefore, the need exists for a low cost and effective two-way communication system (2WC system) for control of the End-users' non-durables, exchange of any type of information between the Multi Utility (and/or a Service Provider (SP)) and the End-users, for performing periodic measurement of the energy consumption and transmitting the data or any other type of information back to the local Multi Utility and/or the Service Provider (SP).

Even though the present invention targets issues traditionally associated with Demand-Side Management (DSM) and Meter Reading, the invention has a far-reaching implication in Electric-Power Markets where End-users are to buy energy at time-varying price (e.g., spot price).

In the deregulated world, the price of electricity is set by auction and can be very volatile. For power companies that buy from the spot market and resell to end-users at a fixed rate, price spikes can result in financial losses and bankruptcy. For End-users paying market price, the inability to watch the hourly price in order to adjust consumption can mean a high monthly bill.

The Value Proposition can be stated as follows:
For End-users: lower energy bill
For society: more efficient use of energy; avoid overinvestment in infrastructure; complement to energy conservation and alternative energy.

The invention allows all End-users to observe price in real time, and can therefore cut back energy usage when the price is too high. The result is what economists call a “price-responsive” (elastic) demand curve. It is well known that a small reduction in demand during a supply shortage, given that all or most End-users participate in the action, can cut down the price drastically. This not only means a lower energy bill for end users but also gives them the collective bargaining power against energy sellers.

Another important factor is that the municipality, governmental bodies or private entities which own electrical utilities, thermal energy utilities, water utilities and/or gas pipelines are looking for synergies within operation, management and maintenance. This may make sense because all these different businesses deal with operation of networks. Some of them therefore form new company structures called Multi utilities, which organize both electrical utility, thermal energy utilities, fresh water utilities, gas utilities, etc, which deliver non-durables to the End-users. In this context non-durables include delivering of:

Mwh in a certain period of time (Electrical Utility)

m³ at temperature T in a given period of time (Thermal Utility)

m³ of fresh water in a given period of time (Fresh water utility)

standard m³ of natural gas in a given period of time (Gas Utility)

standard m³ of other type of fuels in a given period of time

Another type of business that also deals with operation and maintenance of networks is the communication business covering broadband networks, fiber communication networks, etc. Hence, these types of networks and business may be organized and operated by a Multi Utility.

These types of networks providing non-durables to the End-users are similar to electrical networks, with respect to topology and the operators have to secure the delivery of the non-durables to the End-users. From an operation point of view the operators have to handle congestion, secure the delivery, which is comparable with operating of power networks.

Today there exist different ways to perform meter reading of the other non-durables with low labor cost involved like: The End-users may read the meters themselves at an agreed schedule and submit the values of the consumption of the other non-durables by mail, E-mail, via the Internet, or the Multi Utility or other Service Providers may install Automatic Meter Reading (AMR). AMR is a system that performs periodic reading and transmits the End-users consumption of the non-durables by means of a communication infrastructure. Hence, the invention is applicable for networks providing non-durables to the End-users.

### SUMMARY OF THE INVENTION

The invention is a two-way communication system (2WC system) consisting of at least two sub-systems that provide interchange of information between a Multi Utility (and/or a Service) Provider and the End-users and vice versa, i.e. a downstream communication path and an upstream communication path forming a 2WC system.

The invention has two objects to provide:

Downstream communication path: A method, a system, composed of electronic devices and algorithms for transmission of control signals or any other types of data from a Multi Utility (an Electrical Utility, a thermal energy utility, a gas utility, a fresh water utility or a combination) and/or an Energy Service Provider (ESP), and or a Service Provider (SP) to one or several End-users, connected to a network delivering non-durables by means of secure control signals in a modern communication protocol compatible with a commercial broadcasting provider using RDS/RBDS, DAB (RDS=Radio Data System, and RBDS=Radio Broadcast Data Service used in the US, DAB=Digital Audio Broadcast), Internet technologies, any other wired or wireless communication technologies or a combination thereof.

Upstream communication path: A method, a system, composed of electronic devices and algorithms for automatic meter reading (AMR) and transmission of any type of data from the End-users to a Multi Utility (an Electrical Utility, a thermal energy utility, a gas utility a fresh water utility, or a combination) and/or an Energy Service Provider (ESP), and or a Service Provider (SP) by means of secure data transmission in a modern communication protocol compatible with Internet technologies or any other wired or wireless communication technologies or a combination thereof.

These and other objects are realized by a method according to claim 1, a system according to claim 20, a computer program product according to claim 34, a control broadcast signal according to claim 36 and data communication signal according to claim 40. Preferable embodiments of the invention are disclosed in attached dependent claims.

In the appended claims, the term “Multi Utility provider” shall designate a provider of at least one of electric power, thermal energy, fresh water, gas and other types of fuels, and the term shall also include in its meaning a Service Provider (SP) and an Energy Service Provider (ESP).

Advantages

The main advantage of the invention is that management of electrical power demand in an electrical power system may be automated using a commercial radio broadcasting provider, with instant access to the End-users loads utilizing an already existing communication infrastructure. Commercial radio broadcasting is a well established technology worldwide, and the access rate is high since radio signals are available at almost every location and hence also available for most End-users. This technology is inexpensive to purchase, easily installed, easily interchanged and permits the economic automation of for example medium voltage networks including smaller or isolated feeder systems and similar installations.

Certain economic advantages of this invention arises part because special hardware devices encoding or decoding signals from high voltage lines are not required. Other economic advantages arise from the use of commercial broadcast enabling use of lower priced open standard hardware and software in place of proprietary software.

Another important advantage of the invention lies in that restoration of loads that have been disconnected by load shaving according to the invention may be restored in a fast and secure manner by the system for load management according to the invention. This because the magnitude of the shaved load to be restored is known, and so the maximum electrical load power demand upon restoration of the shaved load is also known. Thus automatic calculations may be performed to allow restoration of loads that have been shaved to proceed automatically as soon as the relation between the power demand and the available power in the network reaches a predetermined value. This advantage also make power management systems according to the invention more acceptable to the end users in political terms because smooth restoration of higher electrical loads is enabled without to long delays associated with restoration of power after black outs (power cuts).

Another advantage is that existing power distribution systems may be simply and economically retrofitted with connection point devices and computer program products according to the invention.

An advantage offered by this invention is that it gives the users the complete flexibility of buying energy in accordance with their budget. When the price of energy is high (whether due to scarce resources or to market manipulation by some sellers), the invention allows End-users to automatically reduce their consumption. A small reduction is enough to bring down the price. This means that End-users of electricity are no longer captive End-users; they now have the bargaining power against the producers and sellers.

For other utility networks such as gas, other types of fuel, thermal energy and fresh water, the advantages of using the described 2WC system are low installation cost, quick deployment time, and low variable cost.

### BRIEF DESCRIPTION OF THE DRAWINGS

The present invention will be described in more detail in connection with the enclosed schematic drawings.

FIG. 1 shows a simplified diagram of different functional levels of a centralized power generation unit(s), distributed generation units (DG), power transmission networks, primary and secondary power distribution networks, End-users.

FIG. 2 shows a simplified diagram of functions in a power network including centralized power generation, distributed power generation units, power transmission network, primary and secondary power distribution networks and residential, commercial and industrial End-users, all connected together via a commercial radio broadcast network, any other Information network or a combination.

FIG. 3 shows a simplified and hierarchical diagram of medium voltage and high voltage equipment and functions, and of power distribution to residential, farmers, cottages, commercial and industrial End-users in a power network and power distribution generation units (DG).

FIG. 4a shows a simplified line diagram of residential End-users connected to a distribution part of a power network arranged with a connection point device according to an embodiment of the invention.

FIG. 4b shows a corresponding simplified line diagram of commercial End-users connected to a sub transmission part of a power network arranged with a connection point device according to an embodiment of the invention.

FIG. 4c shows a corresponding simplified line diagram of industrial End-users connected to a distribution part of a power network arranged with a connection point device according to an embodiment of the invention.

FIG. 5a shows a simplified line diagram of distributed generator units (DG) connected to a sub transmission part of a power network arranged with a connection point device according to an embodiment of the invention.

FIG. 5b shows a corresponding simplified line diagram of distributed generator units (DG) connected to a distribution part of a power network arranged with a connection point device according to an embodiment of the invention.

FIG. 6 shows a corresponding simplified line diagram of distributed generator units (DG) and residential End-users connected to a distribution part of a power network arranged with a connection point device according to an embodiment of the invention.

FIG. 7 shows a simplified line diagram of schematic layout to provide meter reading of the energy consumption of End-users, in accordance with prior art.

FIG. 8 shows a simplified line diagram of the downstream communication path, including the courier, the communications infrastructure, the intelligent home gateway (Bbox), the communication path between the Multi Utility provider according to an embodiment of the invention.

FIG. 9 shows a simplified line diagram of the upstream communication path, including the courier, the communications infrastructure, the metering point gateway (Mbox), the intelligent home gateway (Bbox), the internal communication path to the meter, and the communication bridge between the Multi Utility provider and/or a service provider (SP) according to an embodiment of the invention.

FIG. 10 shows a simplified line diagram of the 2WC system according to an embodiment of the invention.

FIG. 11 shows a block diagram of the conversion of system parameters and variables (Inputs) into device addresses and commands (Data), which are then transmitted using a radiobroadcast infrastructure according to an embodiment of the invention.

FIG. 12 shows a block diagram of the intelligent home gateway (Bbox), which receives and decodes the transmitted device addresses and commands (Data) using radiobroadcast infrastructure, processes on received data and acts according to the implemented functions according to an embodiment of the invention.

FIG. 13 shows a block diagram of the metering point gateway (Mbox), which interacts with the intelligent home gateway (Bbox), the metering device and a communication network connected to the utility according to an embodiment of the invention.

FIG. 14 shows a simplified block diagram for a schematic representation of an End-user connected to a electrical power network and the internal communication infrastructure between the intelligent home gateway (Bbox) and the electrical loads within an End-user's premises according to an embodiment of the invention.

In addition FIG. 14 shows the how the intelligent home gateway (Bbox), and the metering point gateway (Mbox), and the connection between the metering point gateway (Mbox), and the electrical meter interfaces with each other with respect to the communication paths, according to an embodiment of the invention.

FIG. 15a is a sketch showing generation, broadcasting, and reception and decoding of the downstream broadcast signal from the Multi Utility provider to the End-users.

FIG. 15b is an indication of the signal blocks constituting the broadcast signal.

FIG. 16 shows a flow chart of the main structure, for a method carried out by several computer program products (A, B & C) according to an embodiment of the invention.

FIG. 17a shows a flow chart for a part of the method carried out by a computer program product A, according to an embodiment of the invention.

FIG. 17b shows a flow chart for a part of the method carried out by a computer program product B, according to an embodiment of the invention.

FIG. 17c shows a flow chart for a part of the method carried out by a computer program product C, according to an embodiment of the invention.

FIG. 18 is a simplified diagram that shows supply and demand curves and indicates the price of electrical energy before and after radio broadcast, according to an embodiment of the invention.

### DESCRIPTION OF THE PREFERRED EMBODIMENTS

The present invention relates to a two-way communications system (2WC system) for supervision, control, automation, metering and measurements of End-users' non-durables, in particular electricity, thermal energy, gas, other types of fuel and fresh water.

The downstream path of the invention is a system of radio broadcast and low-cost devices/switches to provide End-users with:
(a) Price information—so that demand becomes price sensitive.
(b) Crisis information—so that grid operators do not have to resort to rolling blackouts.
(c) Other energy service related information like: Change of energy supplier, advertising of price for different types of energy, advertising, etc.

In other words, the downstream path of the invention has two primary aims.

The first aim is applicable to de-regulated energy markets where End-users buy electrical energy (the product) at a time-varying rate; yet, they do not have the ability to observe price in real time. By radio broadcasting the price, and by providing low-cost means for End-users to observe the price, the invention can reshape their consumption behavior. Specifically, when the price is high, the End-users cut back consumption. Moreover, when many End-users respond to price, the collective reduction alters the demand in the wholesale market, leading to a drop in price. In other words, this “community effect” is the game changer, because it gives the End-users the bargaining power against the energy producers and sellers.

The second aim is applicable to grid operation during emergency, whether the market is regulated or de-regulated. When the grid operator broadcasts emergency commands such as “ration your consumption by 5%” to all End-users, a simple control system at each End-user's site react to the rationing command. The collective ration results in a net reduction of grid loading, without cutting off power supply to anyone. This ration strategy is to replace existing practices such as load shedding and rolling blackouts.

The downstream communication path is a radio broadcast, using the existing commercial radio broadcast networks, in which information is broadcasted from a Multi Utility or other Service Provider, without affecting the normal services in the analogue or digital radio broadcast network. The downstream communication part may utilize for instance the RDS (Radio Data System), RBDS (Radio Broadcast Data Service used in the US), DAB (Digital Audio Broadcast), which is a method for sending information along with standard radio services, or any similar system.

The upstream path of the invention is a system of wireless communication (technology including Mobile telephones, GSM, GPRS, 3G, SMS, Blue Tooth technology, etc.) and low-cost devices to provide Multi Utility companies with:
(a) Consumption information
(b) Security information associated with the End-user's site
(c) Diagnostic information associated with the End-user's site
(d) Information from other systems at the End-users premises, in particularly smart house systems, security systems, etc

For the downstream communication path of the 2WC system, the present invention discloses methods and systems composed of electronic devices and algorithms for controlling of non-durables, such as:
electrical loads connected to an electrical power generation, power transmission and power distribution network,
distributed generation units (DG) connected to an electrical power generation, power transmission and power distribution network,
thermal energy loads connected to a thermal energy network,
fresh water loads connected to a fresh water network,
gas or other types of fuel delivered via a distribution network to energy loads or to production units, such as e.g. distributed generation units (DG)
remote control of electrical loads connected to premises that are used occasionally by the End-user. Examples are cottages that are sited in another geographical area with respect to the End-users home.
control substations including primary components (transformers, breakers, reactive power sources, etc.) connected to an electrical power generation, power transmission, power distribution network
control central located nodes of a distribution network providing gas, other types of fuel, thermal energy and fresh water to a End-user.

The upstream communication path uses preferably the existing wired or wireless phone network to allow many data units to report back to a central place; i.e. at the local Multi Utility provider, at an Energy Service Provider (ESP), at a Service Provider (SP), other types of entities or a combination of one or several.

For the upstream communication path of the 2WC system, the invention discloses a method and a system composed of electronic devices and algorithms for performing automatic meter reading (AMR) of non-durables, such as:
electrical energy and power consumption in electrical loads connected to and electrical power generation, power transmission and power distribution network
remaining fuel, e.g. gas, diesel, etc. in storage devices connected to a fuel distribution network
produced electrical energy in standalone distributed generation units (DG) or units (DG) connected to a to an electrical power generation, power transmission and power distribution network
water consumption in thermal energy loads connected to a thermal energy network
consumption of fresh water in fresh water loads connected to a fresh water network
fuel consumption, e.g. gas, diesel, etc. in standalone distributed generation units (DG) or in units (DG) connected to an electrical power generation, power transmission and power distribution network
remote meter reading of periodic consumption of energy at premises that are used occasionally by the End-user. Examples are cottages that are [symbol] tted in another geographical area with respect to the End-user's home.
consumption of electrical energy downstream and power loading on primary components upstream and downstream for substations connected to an electrical power generation, power transmission, power distribution network
consumption of non-durables in central locations of a distribution network providing gas, other types of fuel, thermal power and fresh water to a End-user.

As opposed to conventional approaches to 2WC systems, this invention involves a hybrid system in that it employs different technologies in each path (the downstream and the upstream communication path) of the 2WC system's information flow.

An End-user is defined as the owner of the non-durable loads sited in his premises. The non-durables are delivered via a distribution network, that is connected to a large infrastructure or connected to a small standalone network. Distributed generator units (DG) may be connected at different places in the network, both in the large infrastructure or in the standalone network. The premises may be a residential home, a commercial building or complex, a hospital, a nursing home, an industrial building or complex, a farm, a cottage, or any type of premises that requires supply of non-durables.

A Multi Utility is defined as an Electrical Utility, a thermal energy utility, a fresh water utility, or a utility that provides supply of gas or other types of fuels.

A Service Provider (SP) and an Energy Service Provider (ESP) is defined as, other players delivering energy and/or services to these markets or a combination of both.

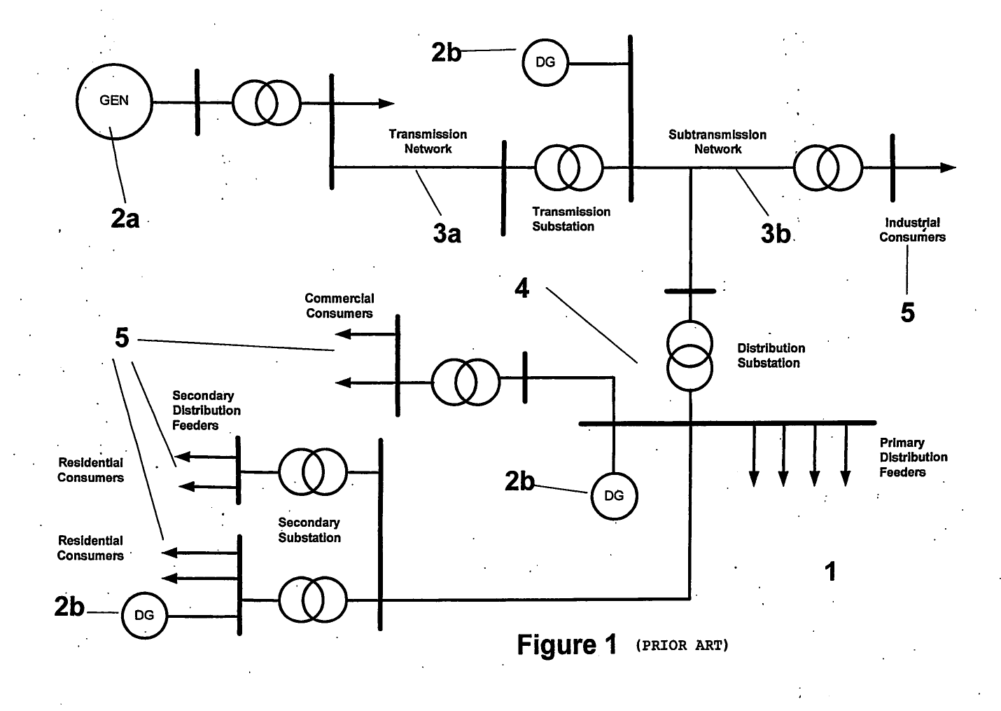

FIG. 1 shows an electrical power network 1 for electrical power generation, main and sub transmission, primary and secondary distribution. The electrical power network 1 includes a power generation facility 2a, a plurality of distributed generation units (DG) 2b, a transmission section 3a, a sub transmission network 3b, a distribution section 4, and a plurality of End-users 5.

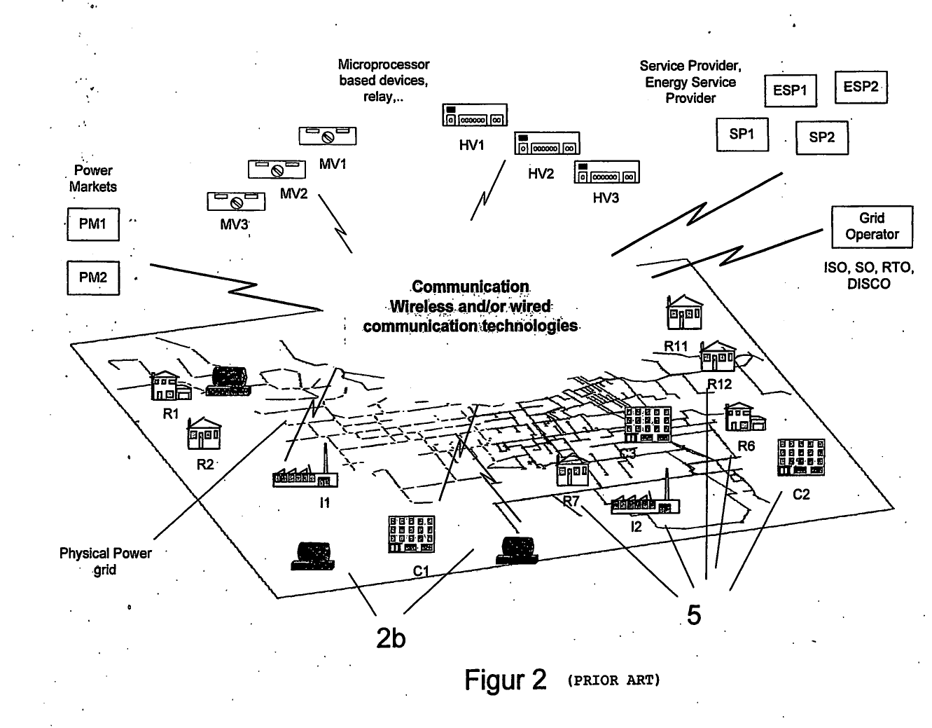

FIG. 2 shows distributed generation units (DG) 2b and End-users 5 in a conceptual diagram with other function of and participants in an electrical power network such as: ISO (Independent System Operator), SO (System Operator), RTO (Regional Transmission Operator), TSO (Transmission System Operator), Local utilities (DISCO), PM (Power Markets), ESP's (Energy Service Providers) and SP (Service Providers).

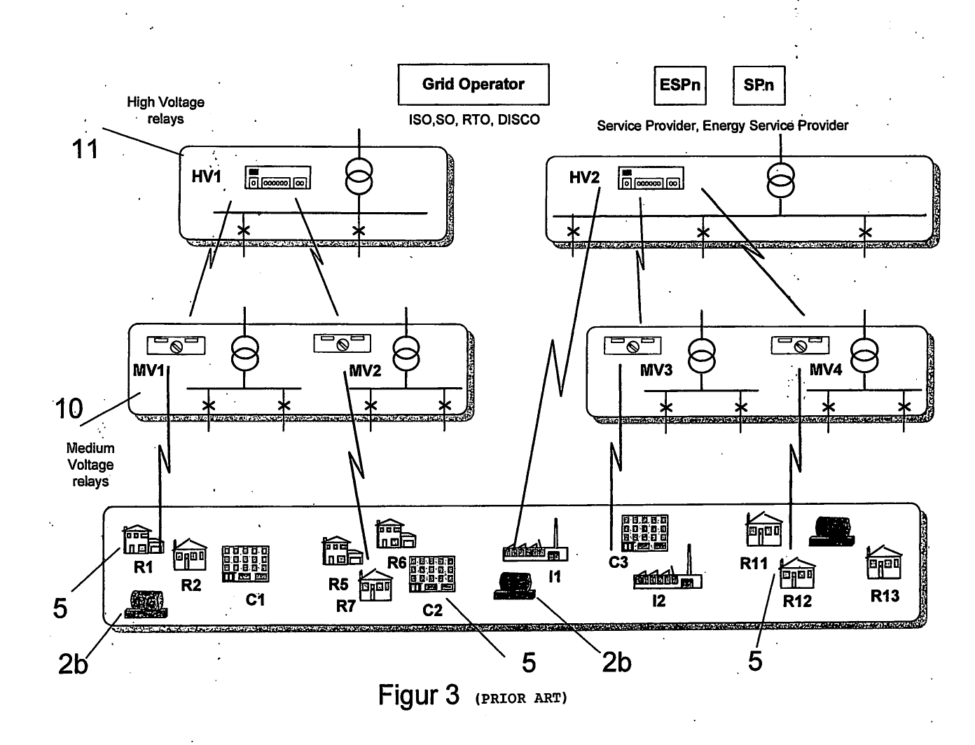

FIG. 3 shows a simplified diagram of different functional levels of a power network, including a centralized power generation unit, distributed generation units (DG) 2b, main and sub transmission networks, primary and secondary distribution networks and End-users 5.

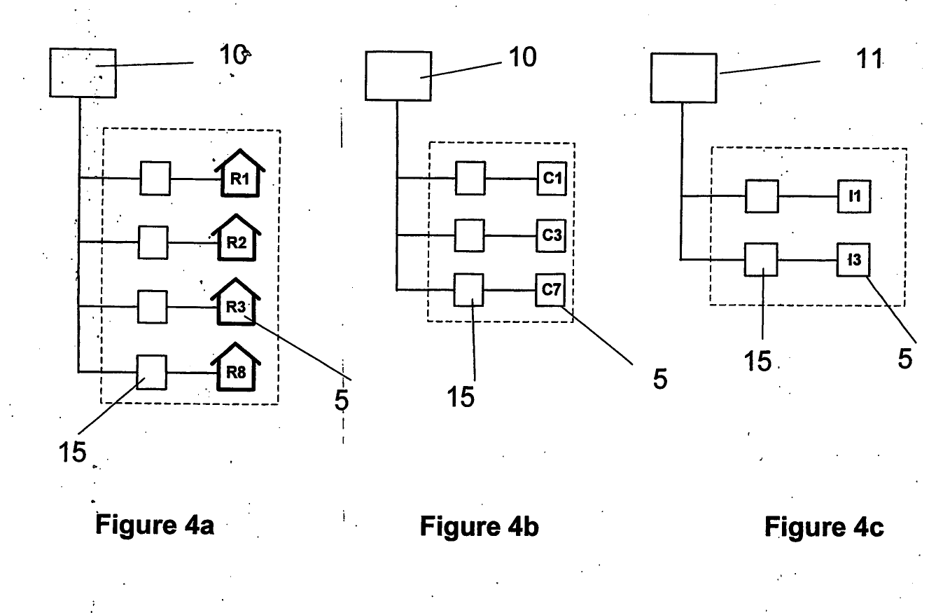

FIG. 4a illustrates a plurality of residential End-users 5, detailed as End-users R1, R2, R3 and R8 each arranged connected to a medium voltage distribution power network controlled by a connection point device 15.

FIG. 4b illustrate a plurality of commercial End-users 5, detailed as commercial End-users C1, C3 and C7 each arranged connected to a medium voltage distribution network controlled by a connection point device 15.

FIG. 4c shows a corresponding arrangement for a plurality of industrial End-users 5 detailed as industrial End-users 11 and 13 connected to the sub transmission network 3b and controlled by a connection point device 15.

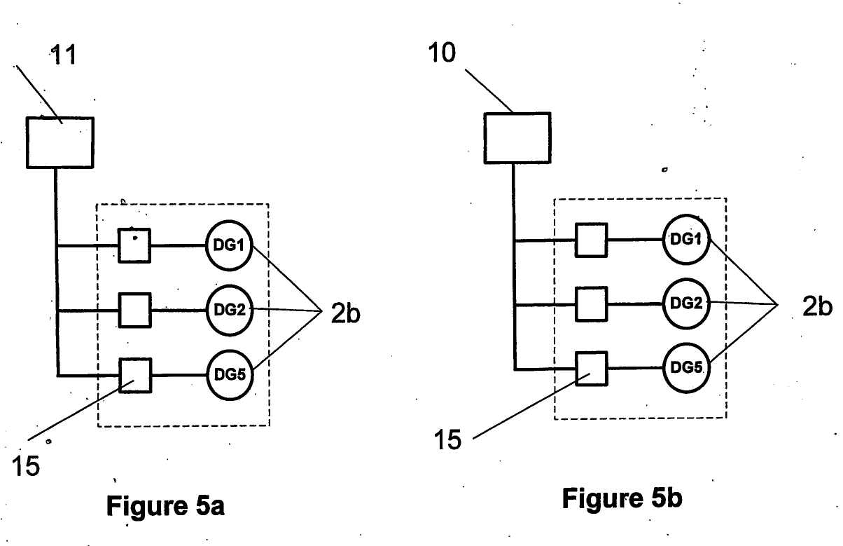

FIG. 5a illustrates a plurality of distributed generation units 2b, detailed as distribution generation units DG1, DG2 and DG5 each arranged connected to the sub transmission network 3b controlled by a connection point device 15.

FIG. 5b illustrates a plurality of distributed generation units 2b, detailed as distributed generation units DG1, DG2 and DG5 each arranged connected to a medium voltage distribution network controlled by a connection point device 15.

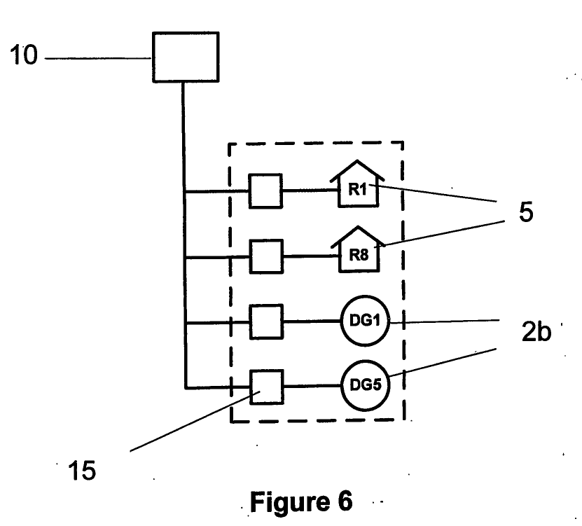

FIG. 6 illustrates a plurality of distributed generation units 2b, detailed as distributed generation units DG1 and DG5 and a plurality of End-users 5, detailed as End-users R1 and R8 each arranged connected to a medium voltage distribution network controlled by a connection point device 15.

The connection point device 15 is arranged at a convenient supply connection point of End-users 5 such as a residential, commercial or industrial user and convenient connection point for distributed generator units (DG) 2b. The connection point device 15, served as a load point device if electrical load is connected or as a generation point device if distributed generation units (DG) 2b are connected or as a combination of both if electrical load and distribution generation units (DG) are connected. The connection point device 15 may include a computer, a processor, a controller of the PLC (Programmable Logic Controller) type, an embedded controller or any combination of the above.

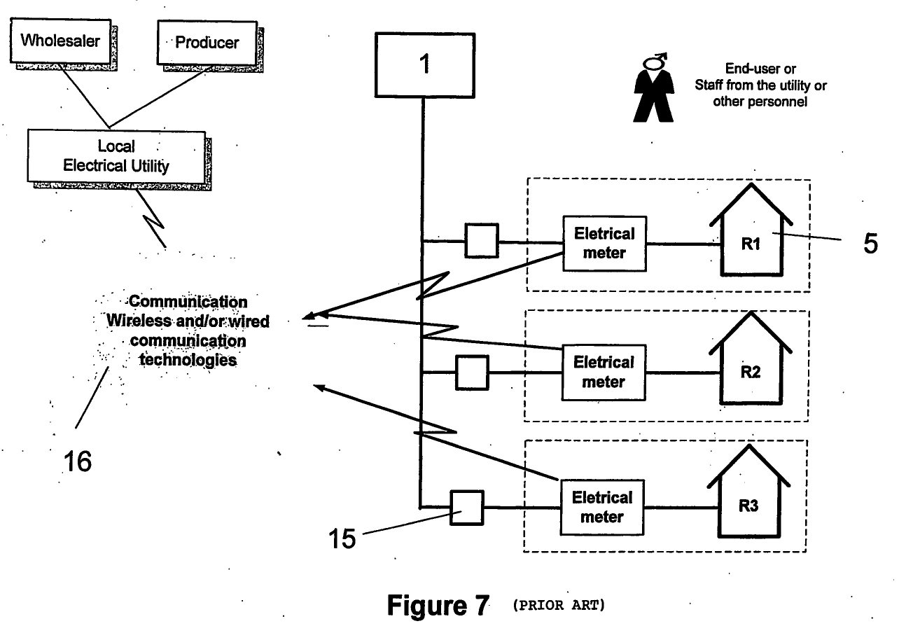

FIG. 7 shows a simplified line diagram of schematic layout to provide automatic meter reading (AMR), manual meter reading by the End-user himself, by other authorized personnel and manual metering by people from the local utility 16 of the energy consumption of residential, industrial and commercial End-users 5. In case of manual meter reading by the End-users 5 or other authorized personnel, the energy consumption may be shipped to the local utility using mail, E-mail, using the local utility's Internet site, by use of telephone or mobile telephone, by SMS or by other any means.

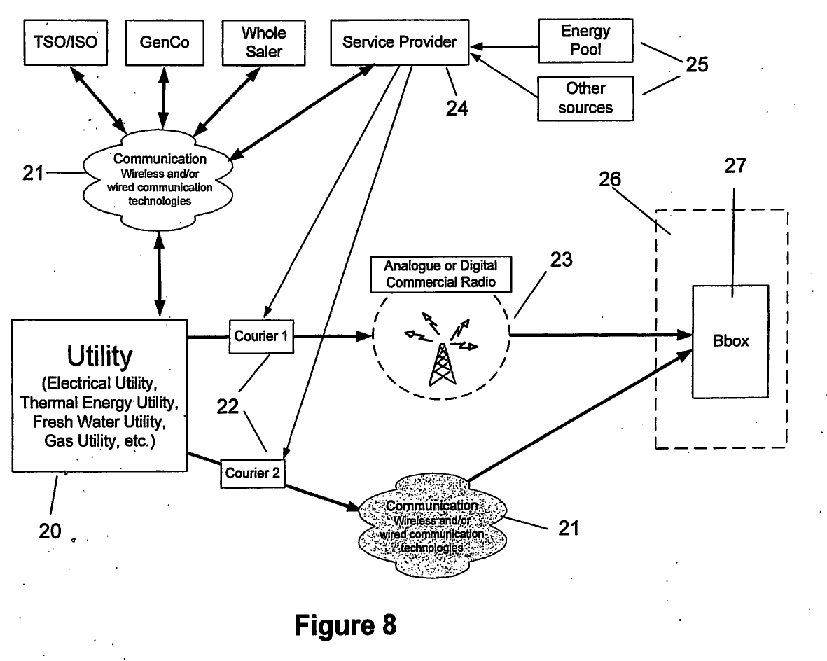

FIG. 8 shows a simplified line diagram of the downstream communication path, including the courier 22, the communications infrastructure 23 ands 21, the intelligent home gateway (Bbox) 27, the communication path between the Multi Utility provider 20 and/or a Service Provider (SP) 24 according to an embodiment of the invention.

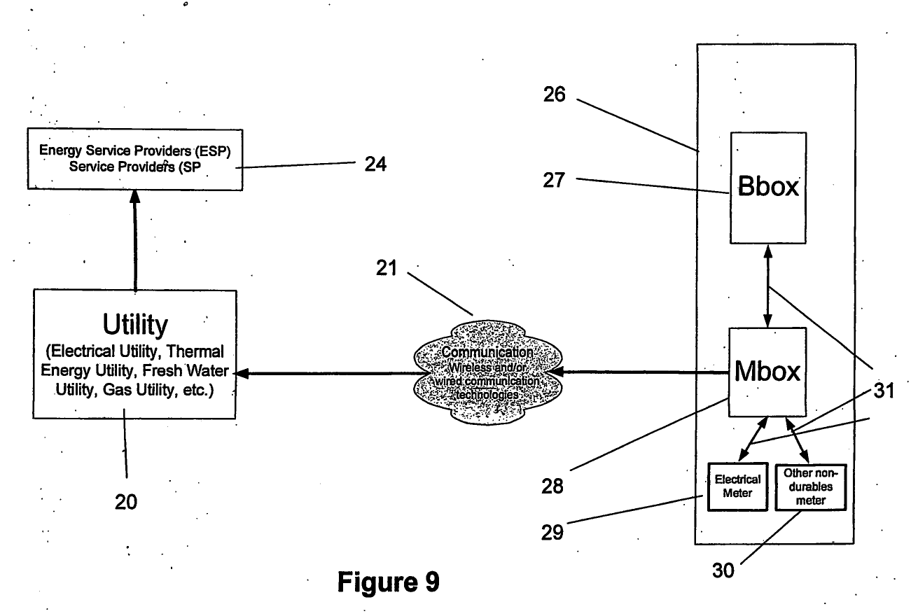

FIG. 9 shows a simplified line diagram of the upstream communication path, including the communications infrastructure 21, the metering point gateway (Mbox) 28, the intelligent home gateway (Bbox) 27, the internal communication path to the meter 31, and the communication bridge between the Utility 20 and/or a Service Provider (SP) 24 according to an embodiment of the invention.

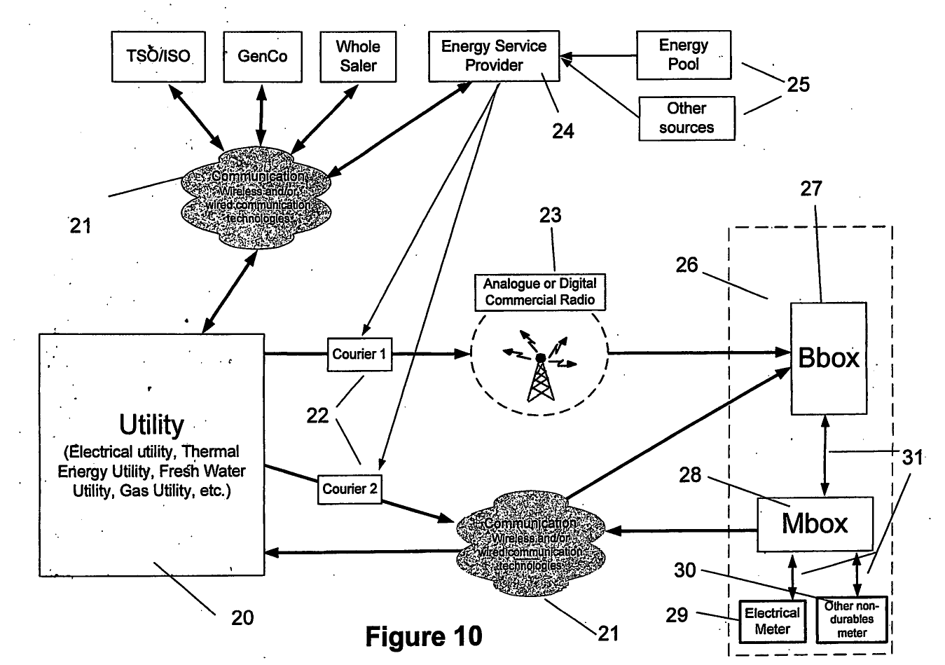

FIG. 10 shows a simplified line diagram of the complete 2WC system, which is formed by downstream and upstream communication parts as described in FIG. 8 and FIG. 9, according to an embodiment of the invention.

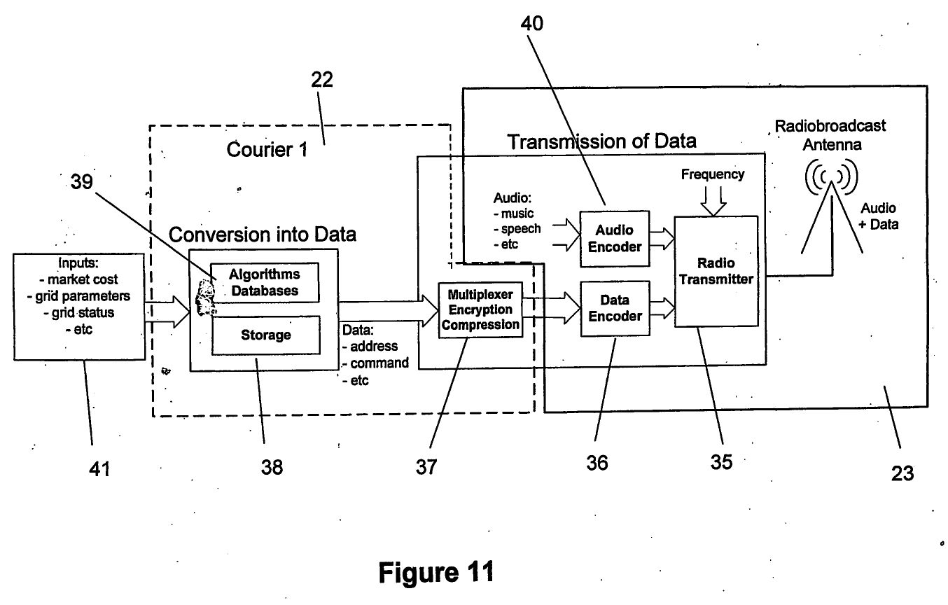

Referring to FIG. 11, system inputs such as grid parameters and status are collected from the relevant players in the energy market, the energy pool and other sources like governmental bodies, regulator, interests organization, etc. These inputs are then converted into device data such as addresses, and commands by means of algorithms and databases (Conversion of Data).

The Data to be transmitted are first multiplexed together, compressed and encrypted (Multiplexer, Encryption, Compression), before being converted into a format according to a suitable encoding standard (Data Encoder).

Conversion of Data and Multiplexer, Encryption, Compression is also referred to as Courier 1, 22 in FIGS. 8 and 10.

Information for error detection and/or error correction may also be added to the Data. The encoded information is then transmitted using radiobroadcast infrastructure (Radio Transmitter and Radiobroadcast Antenna) along with the standard radio services (Audio), without affecting these.

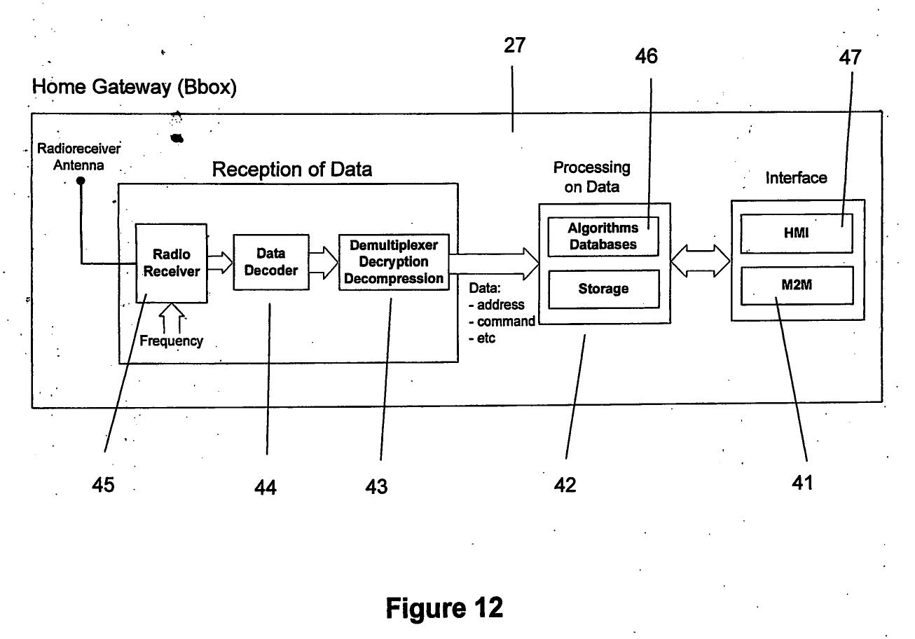

Referring to FIG. 12, the distributed intelligent home gateways (BBoxes) contain a system for reception and decoding of the transmitted Data (Reception of Data) by the radiobroadcast infrastructure.

When the received Data are free of errors or errors have been corrected using transmitted error detection and/or error correction information, Data are then processed upon by algorithms according to implemented and/or commanded functions.

The intelligent home gateway (Bbox) is equipped with a human-to-machine interface (HMI) for providing information to or receiving from an End-user or operator.

In addition the metering point gateway (Mbox) is equipped with a variety of interfaces to other electronics equipment and/or devices and/or systems for the control, monitoring and exchange of data and information. Examples are: personal computers, personal digital assistant, communication devices, advertising means, security and safety systems, smart house systems, energy supply management systems, etc

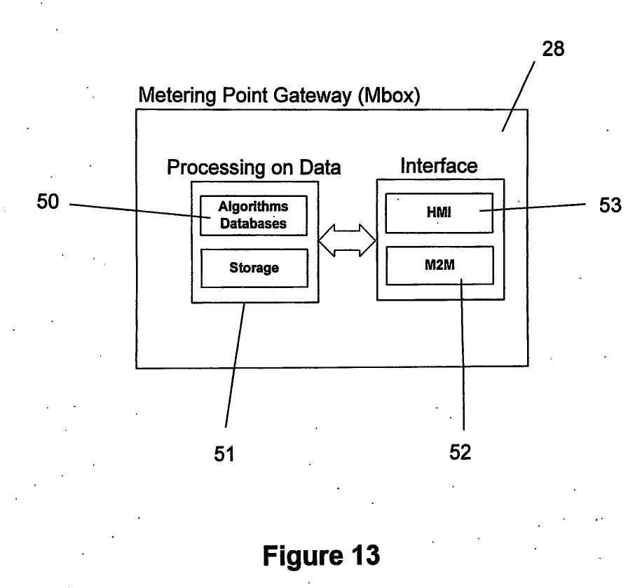

FIG. 13 shows a schematic block diagram of the metering point gateway (Mbox) 28 which acts as a gateway to the Utility and/or Service Provider (SP) via the upstream communication path according to an embodiment of the invention.

In addition, the metering point gateway (Mbox) 28 has built-in algorithms and interfaces for performing metering of non-durables and diagnostics of power networks, fresh water networks, gas networks, thermal heating network and other fuel networks, inside the End-user premises.

The metering point gateway (Mbox) 28 may also have displaying capabilities of measured consumption of non-durables to an End-User via a human-machine-interface (HMI).

The metering point gateway (Mbox) 28 may also serve in the retrofit market by measuring and displaying accumulated consumption of non-durables by mechanical or electro-mechanical metering devices.

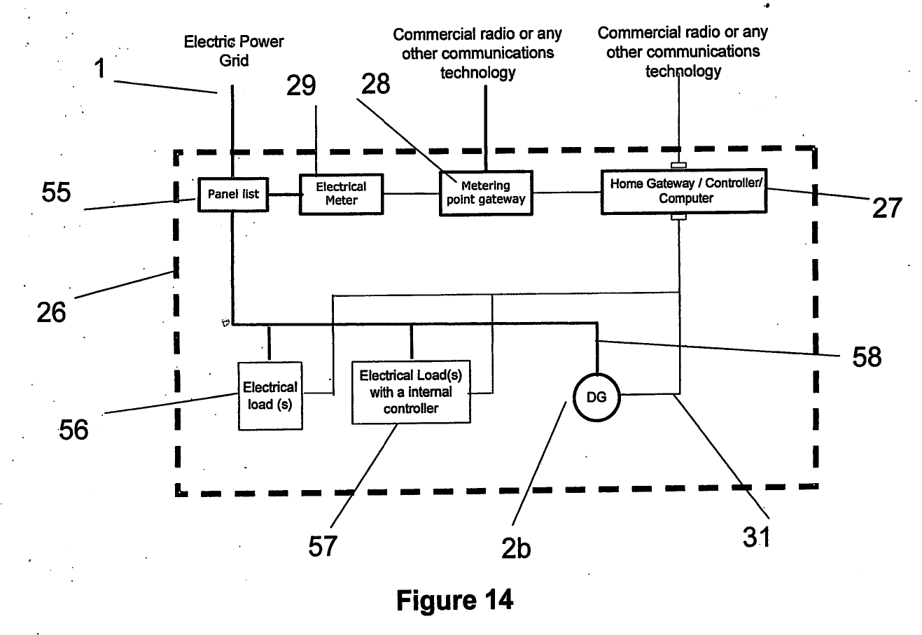

FIG. 14 shows an electrical power grid 1 providing electricity to the customer's premises 26, which are enclosed in the dashed line “xx”. From 1, electric power flows through a panel of breakers and/or fuses 55, and then through electrical wiring 58 to supply a number of electrical loads 56 and 57. The premises might have an on-site power generation 2b, which is an alternative source of energy should grid power fail, or become too expensive. The electrical meter 29 keeps the record of energy consumed (kWh) by the premises. The meter can be read by a human being, but in this embodiment, it is read by the metering point gateway (Mbox) 28, which communicates upstream to a central office. (In many instances, 28 and 27 might very well be housed within one device.) The intelligent home gateway 27 (Bbox) is a radio receiver that gets data from the grid operator or the electrical utility company by means of a specialized information broadcaster. Data can be the hourly price, or a rationing command.

In the simplest case, the data are displayed on the intelligent home gateway 27 (Bbox). For example, the display shows that the price for the present hour is $0.25 per kWh, the customer can decide for himself if this price is to high and whether some of the appliances need to be switched off (and the DG 2b should be switched on or stay off). He can then manually carry out these actions. However, if manual operations are not desirable or possible, some form of automation needs to be made available.

Automated switching of electrical loads is done via an intra-premises communications link 31. This link can be any one of, or a combination of, several communication technologies that are used in home/building automation. Examples include X-10 (which uses the existing power wires as the communications medium), ultrasound, infra-red, radio frequencies, or wireless technologies such as Bluetooth. To facilitate the automated switching of the electrical loads, the intelligent home gateway 27 (Bbox) may include the following units: power supply, conversion and distribution units; processing unit (e.g. micro-processor); human-machine-interface (e.g. Liquid Crystal Display, touch screen, push buttons and Light Emitting Diodes); set of interfaces (e.g. serial, wireless RF, GSM, GPRS, X-10, Infrared, TCP/IP, Ethernet, Internet, ultrasound); receiver for analog and/or digital commercial radio (e.g. RDS/RBDS or DAB) and decoder of transmitted data via mentioned commercial radio broadcast.

Automated switching of loads is described below for two different applications.

Real-Time Pricing:

Via the intelligent home gateway, the user sets the prices that he wishes to accept. For example, he wants to pay no more than $0.05/kWh for the first group of loads, no more than $0.15/kWh for the second group, etc. How often the user changes these settings and the group members depends entirely on his habit and his wallet. On a regular basis (once a day, or once every hour), the prices are broadcast over the airwave, and are received, decoded and stored in the intelligent home gateway 27 (Bbox).

For example, the present time is 06:05, and the broadcast has indicated that the price will be $0.04/kWh after the hour of 07:00, $0.085/kWh after hour 08:00, $0.12/kWh after hour 09:00, $0.25/kWh after hour 10:00, $0.14/kWh after hour 11:00, etc. Consequently, the first group of loads will be shut off after 08:00 (since the price setting for the first group is $0.05/kWh), and the second group off between 10:00 and 11:00. To carry out these actions, at time 08:00, the intelligent home gateway sends out a “Group 1, turn off” command into the communications medium 31, a “Group 2, turn off” at 10:00, and a “Group 2, turn on” at 11:00. Group 1 can be comprised of members of 56 and of 57 in FIG. 14; similarly for Group 2. The actuators inside these members respond to the command (turn on/turn off) automatically.

At any given time, the user can change the price setting. In the example above, when the first group of loads is turned off after 08:00, the user can override this by raising the price for the group to any value greater than $0.085/kWh. It is the ability to choose prices that gives the user the complete flexibility of buying energy according to his wallet and his lifestyle.

Rationing of Loads:

In a typical grid, rationing is very seldom and is needed only when the grid, either entirely or partially, is in a crisis. The requirement to reduce or ration electrical load in a certain area may be derived from reasons such as:
The measured load in a substation has reached its rated nominal capacity
An algorithm has detected that the power system in the certain area is near voltage collapse
An algorithm has detected that the power system in the certain area is close to instability
The energy supply is exhausted

Rationing is to be determined by the grid operator or by some automated decision associated with grid operation, and not by users of electricity. When a ration is issued, the command sent over the airwave typically represents the following: “ration x % of load”.

When the intelligent home gateway at each customer's premises receives this command, it can perform either of the following estimation methods:

The intelligent home gateway then sends a “turn off” command to its targeted actuators on the premises. The power behind the ration is that each site turns off only a small amount of the consumption (around x %), and the collective action over many sites result in the desired load reduction for the grid. Until now, electrical load reduction is typically carried out by “rolling blackouts” or brownouts, resulting in some customers losing electricity completely.

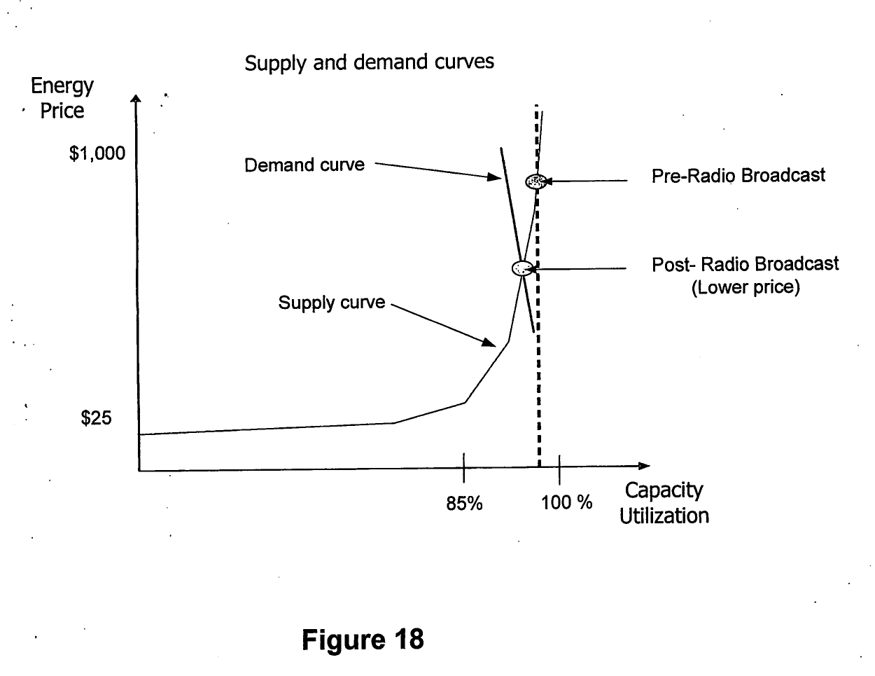

FIG. 18 shows the “network” or “community” effect when end users become responsive to energy prices. The supply curve reveals that the price starts out at $25/MWh at low capacity utilization, increases gradually at first, and shoots up after exceeding 85% of production capacity. The traditional demand curve is that depicted as a vertical curve (dotted line) meaning that the demand curve is price inelastic. The intersection between the supply curve and the demand curve is the equilibrium price, and is labeled “Pre-radio broadcast”. When the energy price is made available to all end users via the radio broadcast technology, people will react to high price by cutting back consumption. This will bend the demand curve from vertical to a slant curve; the new equilibrium price becomes lower as denoted by “Post-radio Broadcast” point.

Data collected for electric-power markets indicate that even a 5% cutback in consumption can instantly bring the price down by 50%. The community effect here means that in order to achieve the desirable result, everybody in, or at least a major part of, the community must participate in the action.

Implementation of the Downstream Communication Path:

The invention may be described as a method to supervise and control an electrical power generating, transmission and distribution power system, by means of an automated load management system, in which load shaving or load shedding actions are carried out by a device arranged at one or more load points and a bundle of load points. The load shaving decisions are calculated in part by use of reference information about each electrical load and each distributed generation units (DG) stored for each connection point device in the system. The connection point device in a preferred embodiment is arranged so as to be able to implement a procedure call that has remotely invoked for control purposes, which remote procedure call is made according to an interface to the commercial radio network or any other wired or wireless communication infrastructure.

The requirement to reduce the electrical load may be derived from reasons such as that:

The measured electrical load in a substation has reached some limit

An algorithm has detected that the power system is near voltage collapse

An algorithm has detected that the power system is not transient stable

The price of electricity has reached a financial limit

The energy supply is exhausted

Load Shaving via Price Signals:

In privatized or deregulated electricity markets, the price of electrical energy varies hourly. However, except for some large energy End-users, price information is not easily observed by the End-users. This is because no one has devised a low-cost solution for the End-user market. This invention proposes the use of commercial radio broadcast (RDS/RBDS or DAB) which is already in use for providing different services (music, news, talk radio, traffic information, advertising. etc.).

More generally, the present invention can be described as a method to manage non-durable demand and production in distributed generation units (DG) automatically connected/disconnected to an electrical power generation, power transmission, primary and secondary power distribution network (1) and to perform automatic meter reading of non-durables, at an End-user's discrete location. Said method including:
encryption of data (prices, commands, . . . ) for distributing “en masse”.
use of commercial radio to broadcast encrypted data via RDS or RBDS or DAB to all End-user locations.
use of an electronic box (Bbox: Intelligent home gateway) at each End-user site to receive, decode, interpret data.
interface of Bbox with electronic switches to switch on or off certain load devices.
use of a metering gateway at each End-user site that sends data (energy consumption, etc.) to a central processing facility. The medium for sending data includes GSM and other phone technologies. The transmission from each site may be done in a sporadic manner (e.g. once an hour, once a day or once a week). In order to prompt a transmission, the central facility may send a wake-up signal to the metering gateway at the site via the broadcast technology.

Broadcast technologies are well suited to distributing data from one central location to many users (point-to-multipoint) in a given area, especially in metropolitan areas where the density of electricity consumption is high. Although these technologies are one-way only, they provide the lowest cost alternative in many applications where high data rates are not required. This communication method is perfect for broadcasting the price signal because the information does not require high bandwidth: electricity price varies only hourly and is set in advance (from several hours to 24 hours ahead of actual happening).

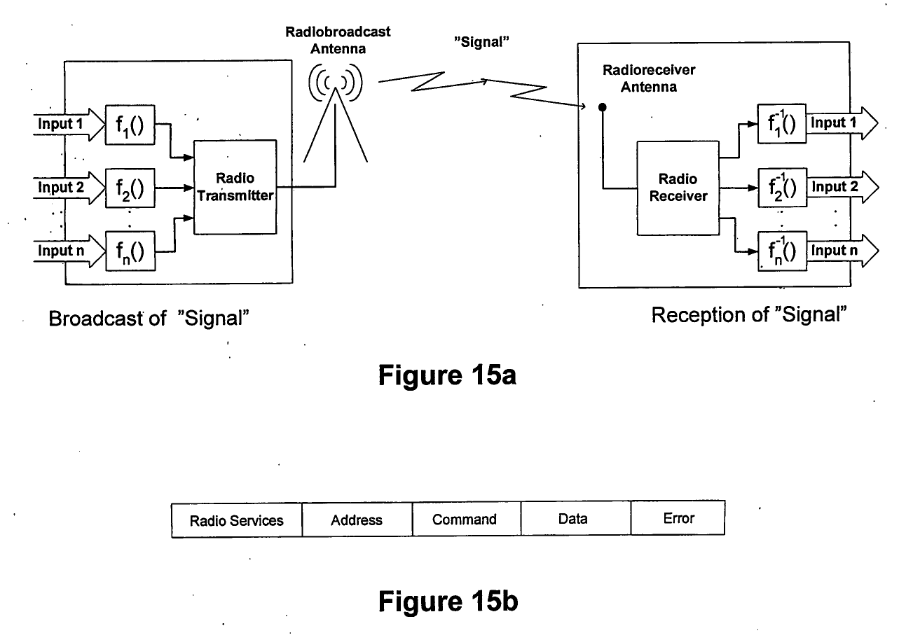

Referring to FIG. 15a, the information (Input 1, 2 and n) is processed upon and eventually converted into a format that is input to a radio transmitter. Processing and conversion is performed by means of functions named f₁( ), f₂( ) and fₙ( ). The radio transmitter may be analog or digital or a combination hereof. Input 1 may for example be speech or music, while Input 2 may be energy information such as for example cost of electricity per kilowatt-hour. The output from the radio transmitter finds its way through a broadcast infrastructure and eventually via a radiobroadcast antenna into the air, taking the form of an electromagnetic signal named “Signal”.

The Signal is received by a radio receiver at the End-user's premises. The outputs from the radio receiver undergo the inverse process as was the case when broadcast Input 1, 2 and n, resulting in Input 1, 2 and n once again.

FIG. 15b shows the contents of “Signal”.

Alongside the standard radio services (Radio Services), such as audio (e.g. music or speech), Data (Address, Command, Data and Error) is transmitted, without affecting the standard radio services. Data is preferably encrypted, preventing unauthorized decoding of the contents.

All distributed electronic devices equipped with a proper radio receiver and decoder, receive and decode Data from Signal.

Both individually and groups of individually distributed electronic devices may be addresses (Address field) and given different types of commands (Command field) and assigned different types of data (Data field).

Examples of commands are:
Switch off the entire electrical load that is controlled by the addressed electronic devices;
Disable or enable subscribed functions and services (e.g. display of cost for electricity).
etc

The transmitted data (Data field), which are received by all distributed electronic devices, but only assigned the addressed devices, may include:

Date and time information;

Cost of electricity for present hour;

Cost of electricity for next 24 hours;

Text to display on for example a display;

etc

The last field (Error field) may contain information for error detection and error correction, in order to maximize reliability of the communication link.

The following describes a typical scenario of how End-users buy electricity:
The (day-ahead) prices of electricity for the coming 24 hours are broadcast over the airwave.
Specialized electronic boxes (“Bbox”) installed at each End-user site receive the price signal and store the prices in their memory.
A Bbox has the appearance of, and user-interface features similar to, a simple radio receiver, and thus, can be bought and set up by the user, without needing a site visit by a technician.
The user has selected, via some buttons and a display on the Bbox, the prices of electricity that he/she wants to purchase. Prices can be for different groups depending on the importance of the load apparatus on the premises. For example, the “green” group represents the least important group and power to all apparatus in this group (such as porch lamp) should be shut off if the price rises above 5 cents per kWh.
When the price at the present hour exceeds the set threshold (i.e., more than 5 cents in the example), the Bbox first blinks an LED light on its face to give a visual indication that a power cut is taking place, and then sends out a signal to its output port. This output port is interfaced with an existing home-automation interface (such as an X-10 interface, or any of its wireless counterparts), which then turns off the appropriate apparatus (the porch lamp in the example) by sending a command to, for example, the X-10 switch that feeds the porch lamp.
At any time, the user can change the price threshold. If he is entertaining his guests at the front porch, and the porch lamp turns off, he simply raises the price for the “green” group and the lamp is turned on again.
Not all load apparatus is meant to be controlled via the Bbox. If the user is willing to pay any price to run his refrigerator, he simply plugs the refrigerator directly into the wall outlet.

The action of reducing consumption during periods of high prices is aimed at reducing the energy bill for the end user. This reduction has two components. The first component is obvious because one pays less by consuming less. (This can be called the “individual” impact.) The second component is analogous to what economists call a “network effect”: when sufficiently many End-users become responsive to price, the collective reduction in demand becomes sufficient to bend the demand curve in the wholesale market, leading to a drastic drop in the equilibrium price, meaning an even deeper saving. (This can be termed the “community” impact.)

Load Shaving via a Rationing Command

Radio broadcast is very effective during emergency because of its ability to reach the intended audience instantly and simultaneously compared to traditional communication technologies such as, e.g. wired or wireless phone networks, PLC, GSM modems, analogue modems, etc.

The following describes a typical scenario of this use:
Grid operator realizes an emergency on the grid. A reduction in consumption is needed. The operator informs a specialized information broadcast company.
The specialized information broadcaster sends out a rationing command, e.g., 5% reduction.
At each site, the Bbox turns off the loads that have been pre-specified by the site owner as “interruptible” (this could be, for example, the group of apparatus with the lowest price setting).
Once a load is turned off due to rationing, the site owner cannot override.
After a time lapse (say 5 minutes), the operator decides if another round of rationing is needed. If yes, the Bboxes will turn off the next block of loads for each site.
At some time later, the operator decides that the emergency is over. The specialized information broadcaster sends out a “de-rationing” command. The Bboxes react accordingly and turn selected loads back on.
It is noted here that rationing can be achieved by an indirect means: the broadcaster can send out a very high price.
   Other Energy-Related Uses of Radio Broadcast:

In addition to price signals and rationing, the radio broadcast has other applications in order to safeguard the national grid.

Price Signal for End-Users:

In this application, the Bbox simply receives and displays the prices, but takes no action. The End-user, upon seeing the prices on the display, can decide for himself whether to turn off or turn on certain loads.

Price Signal for DG Participation:

The above describes the use of radio broadcast in conjunction with Bboxes to allow energy users to select the prices at which they want to buy energy. By a similar token, the same Bbox can be used by the DG owner to decide when to supply energy to the power network or when to disconnect from the grid.

Load Relief for Critical Power Equipment:

This feature is similar to that of a rationing described above, except that it affects only a smaller geographical area. For example, a transformer at a distribution substation is overloaded. The broadcaster sends out a rationing command to all Bboxes at sites downstream from the mentioned transformer. The sites collectively cut back their kWh usage, thus preventing the transformer from failure, which would have meant a blackout to the downstream community.

“Weather-Smart” Load Control:

The national weather service forecasts that a severe storm is approaching.
The specialized broadcaster sends out a message.
At each site, Bbox studies the message to see if it is a target.
Non-essential loads at target sites are shut off.
After the storm has passed, the broadcaster sends out a new signal. All loads are turned back on automatically.
Why this feature: to lessen the loading on the grid to make it safer. Should a power line be knocked down by the storm of lightning, it is much less likely for the event to trigger a chain reaction.
   Service Restoration:

The invention also provides for load restoration, which is also carried out by the device arranged at one or more load points. The load restoration decision is carried out by use of reference information about each load stored for each load point device in the system. The effect of one or more load restoration actions is to provide an incremental restoration of load in known increments.
The city is in a blackout. The grid company attempts to restore service. This is a tricky operation (lots of hits and misses) because nobody knows what are being kept “on” at the End-user sites. (It would have been nice if customers had turned off everything!)
The specialized broadcaster, working in conjunction with grid operator, sends out “restoration” signals.
At each site, Bbox responds to the instruction by permitting “just a few” loads.
The operator connects the city to the grid. At each End-user's site, the first chunk of loads is turned on.
The broadcaster sends out another signal. The process continues until all the loads are restored.
Why this feature: to remove the guesswork from operator's decision; faster time to bring grid back to service.
   Test Schemes for Grid Protection/Control:
The Challenge: grid emergency happens only rarely, and the control schemes devised for them are thus rarely put to the real test. The actuators (breakers, switches) may fail miserably during a real event.
The solution: The specialized broadcaster can be relied upon to test the performance of emergency controllers. How: if the control in question involves load shedding, the specialized broadcaster can mimic a load shedding by testing a load rationing.

Unlike electric-power networks, other utility networks (such as water and gas) do not face the challenge of balancing generation and consumption in real time; however, they can also benefit from the described downlink system. The downstream link can be used for broadcast in case of network emergency (such as when water or gas become scarce), and the Bboxes respond by rationing usage.

Implementation of the Upstream Communication Path:

The invention may be described as a method and a system to perform automatic metering of non-durables, like electricity, gas and water at End-users discrete locations connected to an electrical power generating, transmission and distribution power system, by means of an automated system and an upstream communication path.

In particular, this invention focuses on (a) utilizing an existing communication infrastructure, and (b) minimizing the variable cost of utilizing that communication infrastructure with respect to automatic metering of non-durables.

The main elements of the proposed upstream communication path are for automatic meter reading of electrical energy consumption and exchange of any type of information from End-users to an Electrical Utility and/or an Energy Service Provider (ESP):
Multiple wireless modems (GSM, 3G, etc.) have the same PIN card.
Only one modem can be on at anytime. Thus all modems appear as one phone to the phone company, which is a method for minimizing the variable cost of using the phone infrastructure.
Specialized electronic sub-boxes (“Mbox”) installed at each End-user site are connected to the electrical meter unit and the Bbox.
The downstream path (RDS/RBDS or DAB) and the Bbox are used to selectively turn on GSM modems. See details below:
Step 0: all GSM modems are off.
Step 1: The broadcaster transmits via the Bbox, an ID=n to wake up modem #n.
Step 2: Mbox at site #n recognizes the wakeup signal. It turns on its modem. Meanwhile, Mboxes at other sites stay silent.
Step 3: GSM modem at site #n dials a preset phone number, and subsequently sends data over the GSM phone network (data=kWh, etc.)
Step 4: GSM modem at site #n turns itself off.
Step 5: The broadcaster selects the next n, and the process continues at step 1.

The main elements for automatic meter reading of gas or other types of fuel, thermal water and fresh water work in principle in the same way as described above.

The return uplink signalling is effected instantly or semi-instantly, meaning that for instance in a case of grid crisis as treated above, instant consumption values may be reported, while in a normal case, consumption values for a time period of one hour or even longer may be used.

The invention is in part carried out by means of a computer program product. The computer program product is also summarily described here as comprising software portions or computer program code elements for carrying out those steps and calculations of the method according to the invention that are executed by the intelligent home gateways (Bbox) and the metering point gateways (Mbox).

Similar to electric-power networks, other utility networks (such as water and gas) require meter-reading activities. The upstream-link as described can be used to regularly bring meter data (thermal water consumption, water consumption, gas consumption) to a central facility. The downstream link is used to select which meter at a certain geographical site is to report.

Signalling System

The broadcast part of the 2WC system (i.e., downstream) contains the following information in the signal (see FIG. 15b):
Data field: The data can be prices, such as twenty-four prices for the next twenty-four hours. Data can also be a set of instruction for the intelligent home gateway (Bboxes) to upgrade their internal programs. Data can also contain a clock signal to synchronize all the intelligent home gateways (Bboxes) with a centralized clock.
Command field: Command refers to a specific instruction from the central facility, such as rationing, service restoration, etc.
Address field: to inform which ones of the intelligent home gateways (Bboxes) should react to the contents of the data field and the command field. By properly setting the address field, the signal can be meant for the entire population, or only a group, or just an individual. For example, if the purpose is to broadcast the “market-clearing prices”, the address indicates the entire population and all the intelligent home gateways (Bboxes) recognize the broadcast. If the purpose is to broadcast the price offered by a particular energy provider, the address must contain an appropriate subfield so that only the intelligent home gateways (Bboxes) that buy energy from that provider will recognize the broadcast. If the purpose is to ration loads within a geographic area, the address must contain a subfield to indicate that geographic area, and only the group of intelligent home gateways (Bboxes) residing in that area will react to the radio broadcast.

At the sending end, the signals are encrypted prior to broadcast. At the receiving end, the intelligent home gateways (Bboxes) use their own programs to decrypt the signals (as well as checking for transmission errors) and turn the decrypted signal into appropriate actions. Encryption and decryption are crucial to safeguarding the communications system from malicious hackers or sabotage.

Next, we discuss the information flow for the upstream path. There are two ways that the central facility (such as a control room) measures customers' response to its radio broadcast:

To observe collective response from the intelligent home gateways (Bboxes), the central facility can check for SCADA/EMS data (grid congestion, grid voltage, line flows, transformer loading, etc.). This is needed to decide what the next broadcast should be. For example, to provide relief to an overloaded transformer, the central facility sends out a rationing command to all the intelligent home gateways (Bboxes) downstream from the transformer. By monitoring the transformer (through SCADA/EMS), the central facility knows whether there is a need to issue another rationing command or not.

To record individual responses, it is necessary that each intelligent home gateway (Bbox) be accompanied by one metering point gateway (Mbox), which has the ability to send data upstream. The data do not have to be sent in real time; rather, the metering point gateway (Mbox) records the energy consumption together with the time information (such as kWh consumed over each hour of the day) and sends a batch at a later time as instructed by the central facility. Because the price varies every hour, the ability to record data on an hourly basis (i.e., the consumption profile) is important to compute a fair monthly bill for each End-user.

In cases where it is impractical or uneconomic to equip each site with a metering point gateway (Mbox), this invention proposes an approximation method to compute a fair monthly bill for each End-user. The approximation method uses the substation recording (from revenue meters, which have the ability to record data on an hourly basis) to generate a profile for all End-users supplied by the underlying substation. This profile is then re-scaled and used as the profile for each of the End-users downstream.

Description of the Computer Program Products

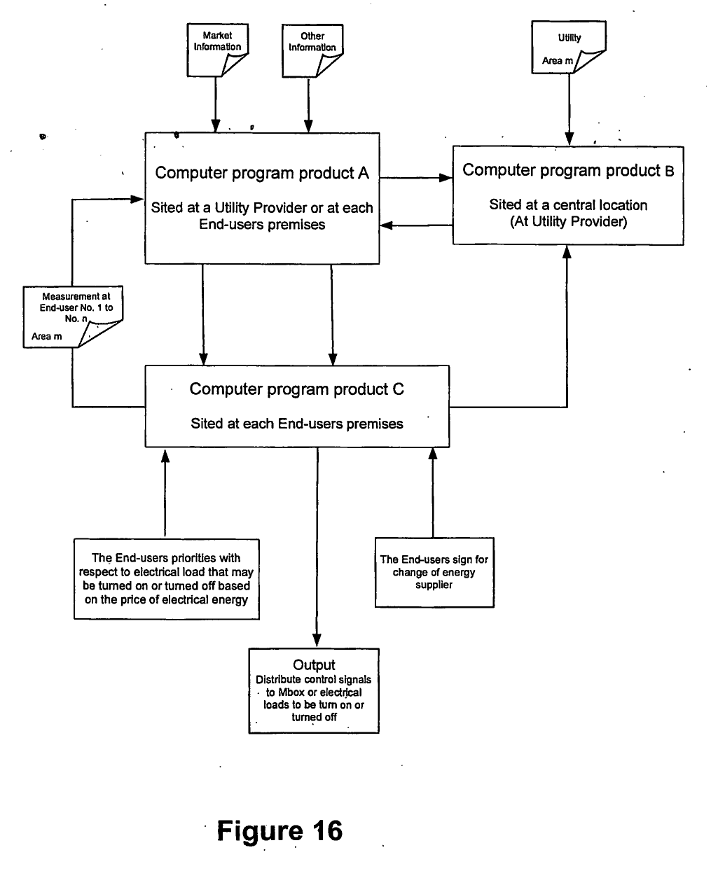

FIG. 16 shows an overview of the flow of information between computer program products A, B and C and the different external inputs.

Computer program A may be located at the Multi Utility provider or located in the intelligent home gateway Bbox at the End-users premises. A handles the input from the market, other types of relevant information, the actual measurement of the periodic energy consumption from End-users and the input from computer program product B. The output of the computer program product A is transferred to computer program B and C, respectively.

Computer program B has to be located with the Multi Utility provider. The input to B is information from utilities, regarding infrastructure topology, connected primary components and mode of operation. The output of computer program product B is input to computer program product A, and is information regarding available load to be turned-on or turned-off downstream of a specific transformer station, where the End-user is connected.

Computer program C is located in the intelligent home gateway Bbox at the End-users premises, and this computer program product handles the input from the computer program product A and the End-users priorities. The output from computer program product C is which electrical loads shall be turned-on or turned-off based on the End-users' terms. Computer program product C also provides automatic periodic measurement of energy consumption and collects other relevant information connected to the End-users internal power system and transfers these data to the computer program product A.

Description of the Implementation

Computer Program Product A

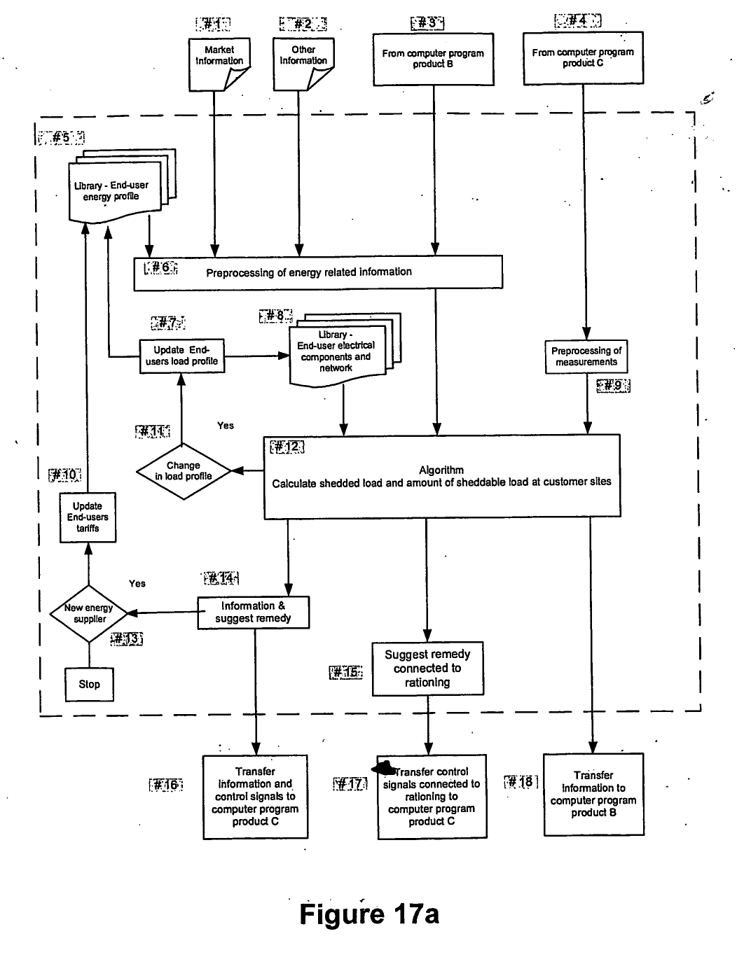

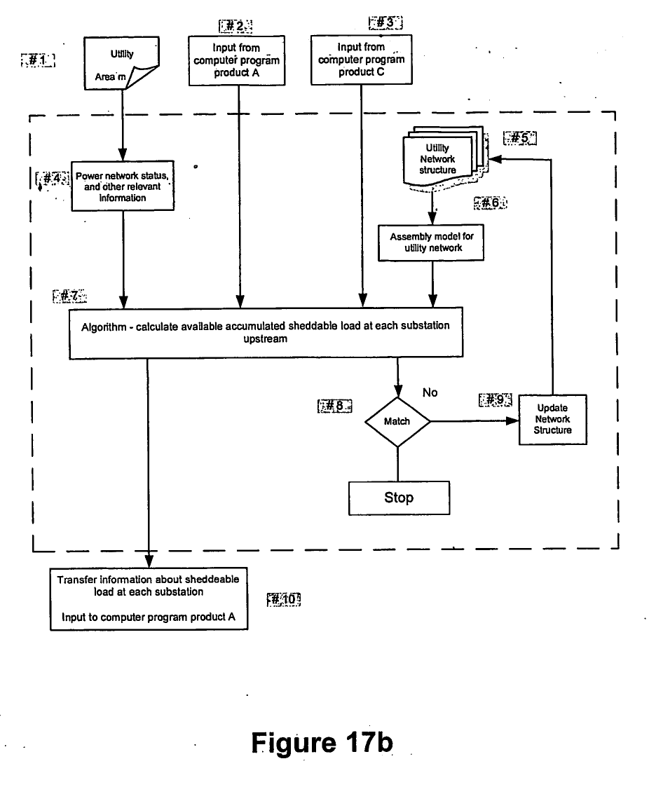

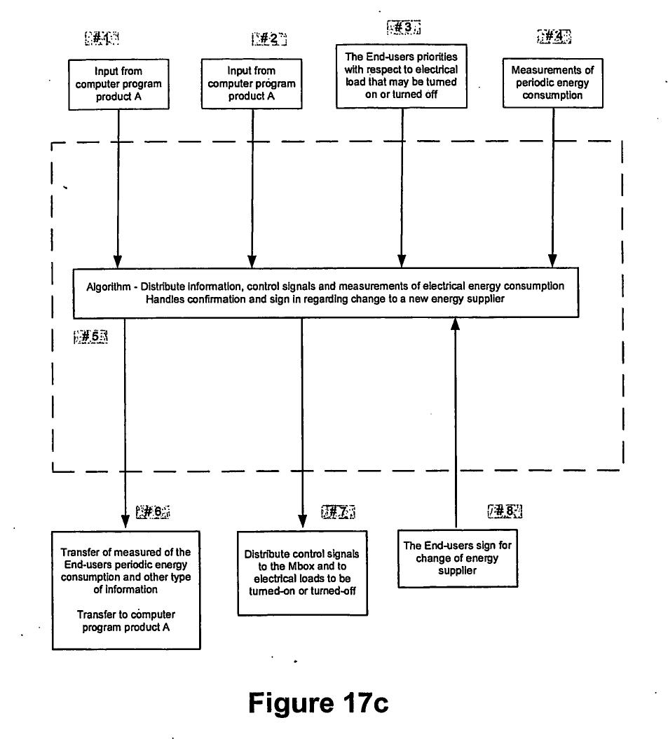

FIG. 17a shows computer program product A more in detail and how the computer program product A, exchanges information with computer program products B and C, respectively. These computer program products describe a process, a method and a system which reduce the cost of delivered energy for End-users. The mentioned computer program product also gain planning, operational, increased reliability for electrical utilities, power producers and Wholesalers. In the following each block or process is described in detail

#1: Market Information

The Block: “Market information” or # 1, represents continuously collected information connected to the electrical energy market. This information is available trough existing program modules and is a characteristic of the energy market which is used in the entire decision process.

#2: Other Information

The Block: “Other information” or # 2, represents continuously collected information from relevant sources concerning:
Data for historical prices of electrical power and energy
Data for continuously prices connected to different contracts regarding supply of electrical energy
Data for present and historical prices for transportation cost in the power distribution grid, where the End-user is connected
Data for present and historical prices for transportation cost in the regional and transmission power grid
Continuously logging and overview of data connected to different prices for delivery of electrical energy from wholesalers

This information is made available trough existing program modules and is a characteristic of the energy market which is used in the entire decision process.

#3: Input from Computer Program B

The Block: “Input from computer program B” or # 3, represents continuously collected information regarding amount of available sheddable load in each transformer station downstream.

#4: Measurements at End-User No. 1 to No. n

The Block: “Measurement at End-user No. 1 to No. n” or # 4 in FIG. 16, (this is referred to input from Computer program product C) represents continuously collected measurements for n End-users connected to a specific geographical area “m” associated with:
Consumption of active electrical power and energy
Consumption of reactive electrical power and energy
Fault on appliances connected to the End-user's internal power network
Fault connected to the End-user's internal power network
Results from diagnosis of the End-user's electrical power system or connected appliances

This information is made available trough existing data program modules for collecting purposes and receipts as a characteristic of the End-users which is used in the entire decision process. This information is made available directly from the End-User's metering point gateway (Mbox) or from the actual electrical utility.

#5: Libraries—End-User's Energy Profile

The Block: “Library-End-user's energy profile” or # 5, is a generic collection of program modules which describe mathematical power and energy consumption (heating equipments, heaters for hot water electrical motors, etc). In addition this block contains one or several sets of historical data of the End-user's load profiles (power and energy) for each electrical component and bundled together for periodic time intervals.

#6: Preprocessing of Energy Related Information

The Block: “Pre-processing of energy related information” or # 6 represents a set of numerical algorithms, which convert data collected by blocks #1, #2, #3 and #5 to one or several sets of information, parameters or key information. Examples of such numerical algorithms are:

Statistical calculations

Economical calculations

Prediction and estimation of power and energy related information

#7: Update End-User's Load Profile

The Block: “Update End-user's load profile” or # 7, represents a set of elements in a computer which stores changes in:

Periodic consumption of electrical power and energy for End-users

Changes in the End-user's internal power network

Changes in appliances

#8: Libraries—End-User's Electrical Components and Network

The Block: “Library—End-user's electrical network” or # 8, is a number of generic program modules which describe mathematically:

The electrical characteristics of the End-user's appliances

The configuration of the End-user's internal network

This block is performing check of the quality and contains a mathematical model of the appliances in a normal mode and in a faulted mode of operation, respectively. This block is made available from existing material or not published material.

#9: Pre-Processing of Measurement

The Block: “Pre-processing of measurement” or # 9, represents a set of numerical algorithms which convert the output from #4 to one or several sets of information, parameters and key information. Examples of suitable numerical algorithms is: “Windowed Discrete Fourier Transform”, (WDFT), Fourier series, cosines and sinus transformation, cosines and sinus series, statistical series, prediction and estimation of time dependent measurements.

#10: Update End-User's Tariffs

The Block: “Update End-user's tariffs” or # 10, represents a set of computer elements which store changes in:

Tariffs

Contracts for electrical power and energy

#10 can be compiled from existing published material or from unpublished material. The aim of #9 is to update stored data, in such a way that the decision is made in a correct manner, with respect to turn-on or turn-off the electrical load at the End-user's premises.

#11: Change in Load Profile

The Block: “Change in profile” or # 11, is a set of computer elements which compare parameters extracted from historical data to parameters extracted from sampled continuous measurements, connected to:
Periodic consumption of power and electrical energy
Faults in appliances at the End-user's premises
Faults in the End-user's internal power network
Results from a computer program product providing diagnosis of appliances and the End-user's internal power system

The aim of #11 is to update the stored data, so that the decision process may reflect the actual energy load profile in the last measured period.

#12: Algorithm—Calculate Load to be Turned-On or Turned-Off at the End-User's Premises

The Block: Algorithm—Calculate electrical load to be turned-on or turned-off at the End-user's premises” or # 12, is the key algorithm related to generation of information and control signal in order to reduce the cost of the energy supplied to the End-user. The algorithm consists of a knowledge database and a qualitative argument procedure to decide if parameters extracted from the inputs should generate the following:
Information to the End-user in connection with the cost of electrical energy and the competitors price on electrical energy
A set of possible electrical loads to be turned-on or turned-off at the End-user's premises
   #13: New Energy Supplier

The Block: “New energy supplier” or # 13, is a set of computer elements which compare parameters extracted from historical stored data connected for the present energy supplier and parameters extracted from potential energy supplier available in the market, connected to:

Tariffs

Type of contracts for delivered power and energy

#13 may be compiled from existing published material or material from unpublished commercial sources.

#14: Information & Suggest Remedy

The Block: “Information and suggest remedy” or # 14, is a set of computer elements, with two different modes:

Mode A: Manual Operation
Make information available to the End-users and suggest which electrical loads that should be ON or OFF in the next time period in order to save cost connected to energy consumption.

Mode B: Automatic Operation
Make information available to the End-users and automatic provide control signals to “turn-on” or “turn-off” electrical loads, based on the End-user's priorities, in the next time period in order to save cost connected to consumption of energy

In addition, #14 transfers information to #16 about energy prices by change from the actual energy supplier to a new energy supplier.

#15: Suggest Remedy Connected to Rationing

The Block: “Suggest remedy” or # 15, represents a set of computer elements that make the decision connected to:
The amount of energy to be turned-off (turned-on) at an End-user's premises
Store amount of turned-off electrical loads at each End-user
In which geographical area and at which End-users' premises, rationing of electrical energy is performed
   #16: Transfer Information to End-Users

The Block: “Transfer information to End-users” or # 16, represents a set of computer elements that store data from block #14 on a suitable format and make this information available to the End-users trough a communication infrastructure and the intelligent home gateway (Bbox).

#17: Transfer Control Signals Regarding Rationing to the End-Users

The Block: “Transfer information to End-users” or # 17, represents a set of computer elements that store data from block #15 on a suitable format and make this information available to the End-users trough a communication infrastructure and the intelligent home gateway (Bbox).

#18: Transfer Information to Computer Program Product B

The Block: “Transfer information to End-users” or # 18, represents a set of computer elements that store data from block #11 on a suitable format and transfer the information to computer program product B.

Computer Program Product B

FIG. 17b shows computer program product B more in detail and how computer program product B, exchanges information with computer program products B and C, respectively.

The mentioned computer program product is connected to update the model of the electrical utilities infrastructure and calculate the amount of sheddable energy at each substation downstream. The amount of power is provided by a recursive algorithm which bundles each End-user's electrical load profiles together to an equivalent electrical load.

#1: Utility in Area m

The Block “Utility in area m”or # 1, represents the continuously collected information connected to the configuration of an electrical utilities distribution network, which supplies electrical energy to a specific geographical area “m”. Such measurements and information are provided by existing computer based data collecting systems (SCADA/EMS) and give the characteristics of the electrical utilities which is used in the decision process in computer program product B

#2: Input from Computer Program A

The Block: “Input from computer program A” or # 2, represents continuously collected information regarding the amount of electrical load to be turned-on or turned-off in a specific geographical area for each transformer station downstream and mode of operation for the power network.

#3: Input from Computer Program C

The Block: “Input from computer program C” or # 3, represents continuously collected information regarding the amount of electrical load to be turned-off or turned-on in a specific geographical area for each transformer station downstream due to a rationing control signal.

#4: Network Statuses and Other Relevant Information

The Block: “Network status and other relevant information” or # 4, represents a set of numerical algorithms which converts the data generated by block #1 to one or several sets of information and parameters. Examples of suitable numerical algorithms are: “Windowed Discrete Fourier Transform”, (WDFT), Fourier series, cosine and sine transformation, cosine and sine series, statistical series, prediction and estimation of time dependent measurements.

#5: Utility Network Structure

The Block: “Utility network structure” or # 5, is a number of generic computer modules, which represent mathematically:
How each electrical component (transmission lines, power cables, transformers, etc.) for the actual electrical utility is connected together in a certain topology for different modes of operation
Electrical rating of each primary component
Position of different switchgears in the electrical utility power network in connection with to different modes of operation

This library compares mathematical models of primary components and power system infrastructure both in a normal mode and a faulted mode of operation. Hence this library will improve the quality of the decisions made by the software. Block #4 may be complied from existing published material or materials from unpublished commercial sources.

#6—Assembly Model for Utility Network

The Block: “Assembly model for utility network” or # 6, represents a number of numerical algorithms, which convert data collected from the block #5 to a network topology which is consistent with the measurements provided by computer program product A trough input given in block #2. Block #6 is engaged with the quality description and contains a number of mathematical models of primary components in a normal and faulted mode of operation. #6 may be compiled from existing published material or material from unpublished commercial sources.

#7: Algorithm—Calculate Available Accumulated Sheddable Load at Each Substation Upstream

The Block: “Algorithm—Calculate available accumulated sheddable load at each substation upstream”, or # 7, is the most vital part of the invented software related to how much electrical energy is already OFF and how much electrical energy in addition may be turned-off at the End-users' premises, based on their priorities. This algorithm consists of a knowledge database and a qualitative reasoning procedure to decide if the extracted parameters in computer program product A (made available in #2) shall lead to the following control actions:
Amount of electrical power which may be turned-off in a number of transformer stations in a specific geographical area in a normal mode of operation
Amount of electrical power which may be turned-off in a number of transformer stations in a specific geographical area in an emergency mode of operation
Amount of power which may be turned-off in order to achieve a more optimal operation of the power network in a specific geographical area, to shave power peaks in a normal mode of operation

Block #7 may be compiled from existing published material or material from unpublished commercial sources.

#8: Match

The Block: “Match” or # 8, is a number of computer elements that compare parameters extracted from historical data regarding infrastructure for electrical utilities and parameters extracted from continuous sampling of measurements based on #1, connected to:
Each electrical component (transmission lines, power cables, transformers, etc.) for the actual electrical utility is connected together in a certain topology for different modes of operation
Electrical rating of each primary component
Position of different switchgears in the electrical utility power network connected to different modes of operation

The block #8 may be compiled from existing published material or material from unpublished commercial sources.

#9: Update Network Structure

The Block: “Update Network structure” or # 9, represents a set of computer elements which store changes in a suitable database:
Each electrical component (transmission lines, power cables, transformers, etc.) for the actual electrical utility is connected together in a certain topology for different modes of operation
Electrical rating of each primary component
Position of different switchgears in the electrical utility power network connected to different modes of operation

The block #9 may be compiled from existing published material or material from unpublished commercial sources. The purpose is to update the stored data about the electrical utility infrastructure to ensure that the decision in computer program product A is based on realistic data reflecting the actual state of the power system.

#10: Transfer Information about the Amount of Sheddable Load at Each Substation

The Block: “Transfer information regarding sheddable load at each substation” or #10, represents a set of computer elements which transfer the information to computer program product A. The block #10 may be compiled from existing published material or material from unpublished commercial sources.

Computer Program Product C

FIG. 17c shows computer program product C more in detail and how the computer program product C, exchanges information with computer program products A and B, respectively. Input to computer program product C are also the measured periodic energy consumption and the End-user's priorities with respect to which electrical load that should be candidate to be turned-on or turned-off. The output from the computer program is a list containing control signals to be distributed to the electrical loads to be turned-on or turned-off.

#1: Input from Computer Program A

The Block: “Input from computer program A” or # 1, represents continuously collected information and control signals containing a list of which electrical loads to be turned-on or turned-off at the End-user's premises.

#2: Input from Computer Program A

The Block: “Input from computer program A” or # 2, represents continuously collected information connected to control signals containing a list of which electrical loads to be turned-on or turned-off due to a decision of rationing. Rationing is used to shave peak electrical loads in an emergency mode of operation or in a situation with lack of electrical energy available in a specific geographical area, where the End-users are located.

#3: Input from End-Users

The Block: “Input from End-users” or # 3, represents the End-users' priorities with respect to electrical load that may be turned-on or turned-off based on the price of electrical energy in the market.

#4: Measurements of Electrical Energy

The Block: “Measurements of electrical energy” or # 4, represents continuously collected information connected to the measurement of electrical energy consumption at the End-user's premises.

#5: Algorithm

The Block: “Algorithm” or # 5, is an algorithm related to distribution of control signal, collecting of measurement of electrical energy consumption and distribution of information which is displayed on a screen. The algorithm consists of a knowledge database, a qualitative argument procedure and a database for temporary storing of information and data.

#6: Measurements of Electrical Energy

The Block: “Measurements of electrical energy” or # 6, represents continuously collected information connected to the measurement of electrical energy consumption at the End-user's premises. The measurement of the electrical consumption is trigged by the intelligent home gateway (Bbox) and is transferred from the electric meter via the metering point gateway Mbox.

#7: Distribute Control Signals

The Block: “Distribute control signals” or # 7, provides the transfer and distribute the control signals to the different electrical loads which may be turned-on or turned-off. This Block also distributes control signals to the metering point gateway (Mbox) and provides the display of energy related information on a digital screen by request of the End-user.

#8: Change of Energy Supplier

The Block: “Change of energy supplier” or # 8, provides the confirmation and sign in for change of energy supplier. The Block generates and transfers necessary information regarding contracts to the electrical utility, the old energy supplier and the new energy supplier

1. A method for automatic management of demand for non-durables, said method comprising
providing at End-users' premises specialized electronic boxes having
microprocessor capability for performing the following functions:
receiving broadcast control signals from a Multi Utility provider,
calculating whether ON or OFF constitutes a correct condition for any connected non-durable consuming apparatus, on the basis of information contained in said broadcast control signals, stored algorithms and End-user adjustable parameter value settings,
turning connected non-durable consuming apparatuses on and off in accordance with the results of said calculating,
End-users programming said boxes by setting parameter values in accordance with End-users' priorities,
broadcasting from a Multi Utility provider a control signal to be received by said boxes,
said boxes taking automatic turn-off or turn-on action for some non-durable consuming apparatuses in accordance with stored control algorithms, parameter values set by said End-users and information provided by said control signal, and
said boxes transmitting back to said Multi Utility provider instant or semi-instant non-durable consumption values at said End-users' premises, thereby collectively influencing market pricing of said non-durables.

2. The method of claim 1, wherein said End-users set parameter values in accordance with estimated importance of their various apparatuses.

3. The method of claim 1, wherein said End-users set parameter values based on pricing of the non-durables.

4. The method of claim 1, wherein said Multi Utility provider broadcasts a control signal containing pricing information regarding said non-durables.

5. The method of claim 4, wherein the control signal contains pricing information regarding pricing valid for a certain time period.

6. The method of claim 1, wherein said Multi utility provider broadcasts a control signal containing information regarding rationing.

7. The method of claim 1, wherein said Multi Utility provider provides at least one of electrical energy, thermal energy, gas and freshwater to a community of End-users.

8. The method of claim 1, wherein said Multi Utility provider broadcasts the control signal via at least one commercial radio broadcasting station.

9. The method of claim 8, wherein said commercial radio broadcasting station utilizes anyone of the RDS, RBDS and DAB systems for broadcasting the control signal.

10. The method of claim 1, wherein said Multi Utility provider broadcasts the control signal via a satellite radio broadcast system.

11. The method of claim 1, wherein said boxes transmit back consumption values via any of a telephone network and a mobile telephone network.

12. The method of claim 1, wherein communication between said electronic boxes and said non-durable consuming apparatuses inside said End-users' premises is effected by use of PLC technology, preferably in accordance with an X10 standard.

13. The method of claim 1, wherein any one of said electronic boxes is physically or functionally divided in an intelligent home gateway and a metering gateway,
said intelligent home gateway receiving said control signals, decoding them,
calculating ON and OFF conditions for all connected apparatuses and transmitting turn-off and turn-on commands to bring said apparatuses into the calculated condition, while also communicating with said metering gateway, and
said metering gateway performing two-way communication with said intelligent home gateway, performing communication with at least one non-durables metering device, and
transmitting at least metering data to said Multi Utility provider.

14. The method of claim 13, wherein said intelligent home gateway transmits commands for turning connected apparatuses in an End-user's premises off and on, via a Power Line Carrier (PLC) system, preferably an X10 system.

15. The method of claim 13, wherein said intelligent home gateway turns off connected apparatuses in an End-user's premises in accordance with non-durable price thresholds set by the End-user for respective apparatuses or for respective apparatus groups.

16. The method of claim 13, wherein said intelligent home gateway turns off connected apparatuses in an End-user's premises in accordance with a rationing command from said Multi Utility provider and non-durable consuming apparatus priority settings entered by the End-user.

17. The method of claim 1, wherein non-durables production in distributed generation units (DG) attached to any of industrial End-users, commercial End-users and groups/communities of private End-users, is governed by said electronic boxes and in accordance with the End-users' settings and priorities.

18. The method of claim 17, wherein a distributed generation unit (DG) attached to a group/community of private End-users is governed by an algorithm taking all said private End-users' settings and priorities into consideration, said algorithm being stored in a computer memory in a computer dedicated for controlling said distributed generation unit and being in communication with said electronic boxes.

19. The method of claim 1, wherein service restoration from said Multi Utility provider after an outage situation is effected by broadcasting restoration signals to bring about step-wise turning on loads at End-users' premises by appropriate action by said electronic boxes.

20. A system for automatic management of demand for non-durables, said system
comprising
specialized electronic boxes at End-users' premises, with microprocessor capability for performing the following functions:
receiving broadcast control signals from a Multi Utility provider,
calculating whether ON and OFF constitutes a correct condition for any connected non-durable consuming apparatus, on the basis of information contained in said broadcast control signals, stored algorithms and End-user adjustable parameter value settings,
turning connected non-durable consuming apparatuses on and off in accordance with the results of said calculating,
said system further comprising
non-durable consumption metering devices at said End-users' premises, in communication with said electronic boxes, and
a broadcasting network for broadcasting from a Multi Utility provider a control signal to be received by said electronic boxes,
wherein
said specialized electronic boxes are programmable by said End-users for setting parameter values in accordance with said End-users' priorities,
said boxes are operative to take automatic turn-off and turn-on action for some non-durable consuming apparatuses in accordance with stored control algorithms, said parameter values and information provided by said control signal, and
said boxes have transmitting capability for transmitting back to said Multi Utility provider instant or semi-instant non-durable consumption values,
thereby to collectively influence market pricing of said non-durables.

21. The system of claim 20, wherein said broadcasting network is a commercial radio broadcasting network.

22. The system of claim 20, wherein said broadcasting network is a satellite radio broadcast system.

23. The system of claim 20, wherein a return transmission path for transmitting back said consumption values is via any of a telephone network and a mobile telephone network.

24. The system of claim 20, wherein a communication path between said electronic boxes and said non-durable consuming apparatuses in said End-users' premises is a wire path, preferably relying on PLC technology and an X10 standard.

25. The system of claim 20, wherein said broadcasting network includes microprocessor capability for encrypting data to be broadcast to End-users.

26. The system of claim 20, including distributed generation units (DG) for additional production of non-durables, attached to any of industrial End-users, commercial End-users and groups/communities of private End-users, said distributed generation units being governed by said electronic boxes and in accordance with the End-users' setting and priorities.

27. The system of claim 20, wherein anyone of said specialized electronic boxes is physically or functionally divided in an intelligent home gateway and a metering gateway, said intelligent home gateway being capable of receiving said control signals, decoding them, calculating ON and OFF conditions for all connected apparatuses and transmitting turn-off and turn-on commands to bring said apparatuses into the calculated condition, as well as communicating with said metering gateway, and said metering gateway being capable of performing two-way communication with said intelligent home gateway, performing communication with at least one non-durables metering device, and transmitting at least metering data to said Multi Utility provider.

28. The system of claim 27, wherein the intelligent home gateway includes at least one of a microprocessor and an embedded controller.

29. The system of claim 28, wherein an End-user terminal is attached to said intelligent home gateway for presentation of messages to the End-user, decoded by said microprocessor.

30. The system of claim 27, wherein the intelligent home gateway includes a radio antenna and a radio signaling decoder for at least one of the RDS, RBDS and DAB systems.

31. The system of claim 27, wherein the intelligent home gateway has connected thereto a satellite reception antenna for receiving a satellite broadcast signal.

32. The system of claim 27, wherein the metering gateway includes a microprocessor for decoding information from the intelligent home gateway and from said metering devices.

33. The system of claim 20, wherein said non-durable is electric power, said Multi Utility provider is an Electrical Utility provider and said consumption metering devices are electricity meters.

34. A computer program product containing any of software code portions and computer program elements which, when said computer program product is run on any of a computer, processor and controller, causes said computer processor or controller to carry out those steps of the method according to claim 1 that are executed by said electronic boxes.

35. The computer program product of claim 34, included in a computer readable medium.

36. A control broadcast signal for providing operator information to specialized electronic boxes at End-users' premises, thereby to enable automatic management of demand for non-durables provided by a Multi Utility provider, said signal containing at least one of pricing information and rationing information regarding amount of consumption reduction.

37. The control broadcast signal of claim 36, wherein the operator information is contained in
a data field,
a command field, and
an address field.

38. The control broadcast signal of claim 37, wherein said data field is to hold at least pricing data and said command field is to hold at least rationing command instructions, if any, and the address field is to hold at least data regarding which electronic boxes should respond to contents of the data field and the command field.

39. The control broadcast signal of claim 36, wherein said signal is an encrypted signal.

40. In a system for automatic management of demand for non-durables, in which system a Multi Utility provider transmits control signals to a plurality of End-users on a broadcast channel, a data communication signal for providing End-user return information to said Multi Utility provider, thereby to enable non-durables delivery control and pricing influenced by demand, said signal containing at least non-durables consumption information and using a signal channel different from said broadcast channel.

41. A method for return signalling in a two-way communication network between a Multi Utility Provider and a plurality of End-users having intelligent home gateways and metering point gateways, wherein a broadcast signal wakes up one End-user's gateways at a time for collecting non-durables consumption data, and a SIM card that is identical for all End-users, is used for establishing telephone or cellular connection to said Multi Utility Provider for delivering said data.

42. An apparatus for return signalling in a two-way communication network between a Multi Utility Provider and a plurality of End-users, said apparatus being an apparatus at each End-user's premises and comprising
an intelligent home gateway operative to receive a wake-up broadcast signal that triggers metering action, and
a metering point gateway operative to establish telephone or cellular connection to said Multi Utility Provider by means of a SIM card that is identical for all End-users, for delivering metering data regarding the respective End-user's consumption of non-durables.
